(19) United States
(12) Patent Application Publication
(10) Pub. No.: US 2021/0026240 A1
(43) Pub. Date: Jan. 28, 2021

(54) METHOD FOR PRODUCING PATTERN, METHOD FOR MANUFACTURING OPTICAL FILTER, METHOD FOR MANUFACTURING SOLID-STATE IMAGING ELEMENT, METHOD FOR MANUFACTURING IMAGE DISPLAY DEVICE, PHOTOCURABLE COMPOSITION, AND FILM

(71) Applicant: FUJIFILM Corporation, Tokyo (JP)

(72) Inventors: Takahiro OKAWARA, Haibara-gun (JP); Shuichiro OSADA, Haibara-gun (JP); Yuki NARA, Haibara-gun (JP); Shoichi NAKAMURA, Haibara-gun (JP)

(73) Assignee: FUJIFILM Corporation, Tokyo (JP)

(21) Appl. No.: 17/022,282

(22) Filed: Sep. 16, 2020

Related U.S. Application Data
(63) Continuation of application No. PCT/JP2019/011973, filed on Mar. 22, 2019.

(30) Foreign Application Priority Data
Apr. 19, 2018 (JP) 2018-080550

(51) Int. Cl. G03F 7/00; G02B 1/10; G02B 5/22; G03F 7/32; G03F 7/105; G03F 7/42

(52) U.S. Cl. CPC G03F 7/0007; G02B 1/10; G03F 7/422; G03F 7/325; G03F 7/105; G02B 5/223

(57) ABSTRACT

A method of producing a pattern includes a step of forming a photocurable composition layer on a support, using a photocurable composition including a color material and a resin and having an acid value of a solid content of 1 to 25 mgKOH/g; a step of patternwise exposing the photocurable composition layer; and a step of treating the photocurable composition layer in an unexposed area using a developer including an organic solvent, thereby performing development.

### CROSS-REFERENCE TO RELATED APPLICATIONS

This application is a Continuation of PCT International Application No. PCT/JP2019/011973 filed on Mar. 22, 2019, which claims priority under 35 U.S.C § 119(a) to Japanese Patent Application No. 2018-080550 filed on Apr. 19, 2018. Each of the above application(s) is hereby expressly incorporated by reference, in its entirety, into the present application.

### BACKGROUND OF THE INVENTION

### 1. Field of the Invention

The present invention relates to a method for producing a pattern. More specifically, the present invention relates to a method for producing a pattern, by which a negative tone pattern is formed through development with a developer including an organic solvent. Furthermore, the present invention also relates to a method for manufacturing an optical filter, a method for manufacturing a solid-state imaging element, and a method for manufacturing an image display device, each including the above-mentioned method for producing a pattern. In addition, the present invention also relates to a photocurable composition and a film.

### 2. Description of the Related Art

Production of a color filter and the like has been performed by forming a pattern by a photolithography method using a photocurable composition including a color material. As the developer, an aqueous alkaline solution has been used in the related art. In addition, attempts to use an organic solvent as the developer have also been investigated.

JP2014-199272A describes an invention which relates to a method for manufacturing a color filter, including a step of forming a colored layer using a coloring radiation-sensitive composition containing an organic solvent-soluble dye, a polymerizable compound, and a photopolymerization initiator, in which the dye is included in the amount of 65% by mass or more in a total solid content; a step of patternwise exposing the above-mentioned colored layer through a mask; and a step of developing the exposed colored layer using a developer including an organic solvent.

Furthermore, WO2017/038339A describes an invention which relates to a method for manufacturing a colored layer, including a step a of forming a coloring radiation-sensitive composition layer using a coloring radiation-sensitive composition containing a colorant, a polymerizable compound, an alkali-soluble resin, and a photopolymerization initiator; a step b of patternwise exposing the coloring radiation-sensitive composition layer through a mask; and a step c of treating the exposed coloring radiation-sensitive composition layer to form a colored layer, in which the step c is a step of performing either one of a step c1 of performing a treatment using a developer including an organic solvent or a step c2 of performing development using an aqueous alkaline solution, and then performing the other step.

### SUMMARY OF THE INVENTION

In a case of producing a pattern using a photocurable composition including a color material, it is desirable that the pattern forming property is excellent, the generation of residues between patterns is further suppressed, and in recent years, a further improvement in these characteristics is desired.

Therefore, an object of the present invention is to provide a method for producing a pattern, a method for manufacturing an optical filter, a method for manufacturing a solid-state imaging element, and a method for manufacturing an image display device, in which a pattern forming property is excellent and generation of residues between the patterns is suppressed. In addition, another object of the present invention is to provide a photocurable composition and a film.

According to the studies conducted by the present inventors, it was found that the objects can be accomplished by the following configurations, leading to completion of the present invention. Therefore, the present invention provides the following aspects.
<1> A method for producing a pattern, comprising:
a step of forming a photocurable composition layer on a support, using a photocurable composition including a color material and a resin and having an acid value of a solid content of 1 to 25 mgKO/g:
a step of patternwise exposing the photocurable composition layer; and
a step of treating the photocurable composition layer in an unexposed area using a developer including an organic solvent, thereby performing development.
<2> The method for producing a pattern as described in <1>, in which a solubility parameter of the organic solvent included in the developer is 18 to 24 MPa^{0.5}.
<3> The method for producing a pattern as described in <1> or <2>,
in which a CLogP value of the organic solvent included in the developer is 0 to 1.
<4> The method for producing a pattern as described in any one of <1> to <3>,
in which the photocurable composition includes a resin having a solubility parameter such that an absolute value of a difference between the solubility parameter and a solubility parameter of the organic solvent included in the developer is 3.5 MPa^{0.5} or less
<5> The method for producing a pattern as described in any one of <1> to <4>,
in which the photocurable composition includes a resin having a CLogP value such that an absolute value of a difference between the CLogP value and a CLogP value of the organic solvent included in the developer is 2 or less.
<6> The method for producing a pattern as described in any one of <1> to <5>,
in which the organic solvent included in the developer is at least one selected from a ketone-based solvent or an alcohol-based solvent.
<7> The method for producing a pattern as described in any one of <1> to <6>,
in which the organic solvent included in the developer is at least one selected from cyclopentanone, cyclohexanone, isopropyl alcohol, or ethyl lactate.
<8> The method for producing a pattern as described in any one of <1> to <7>,
in which the color material is a pigment.
<9> The method for producing a pattern as described in any one of <1> to <8>, further comprising a step of performing rinsing with a rinsing liquid including an organic solvent after the step of performing development.
<10> The method for producing a pattern as described in <9>,
in which a boiling point of the organic solvent included in the rinsing liquid is lower than a boiling point of the organic solvent included in the developer.
<11> The method for producing a pattern as described in <9> or <10>,
in which a solubility parameter of the organic solvent included in the rinsing liquid is 17 to 21 MPa.
<12> The method for producing a pattern as described in any one of <9> to <11>,
in which a CLogP value of the organic solvent included in the rinsing liquid is 0.3 to 2.0.
<13> The method for producing a pattern as described in any one of <9> to <12>,
in which an absolute value of a difference between a solubility parameter of the organic solvent included in the rinsing liquid and a solubility parameter of the organic solvent included in the developer is 3.5 MPa^{0.5} or less.
<14> The method for producing a pattern as described in any one of <9> to <13>.
in which an absolute value of a difference between a CLogP value of the organic solvent included in the rinsing liquid and a CLogP value of the organic solvent included in the developer is 1.0 or less.
<15> The method for producing a pattern as described in anyone of <9> to <14>,
in which the photocurable composition includes a resin having a solubility parameter such that an absolute value of a difference between the solubility parameter and a solubility parameter of the organic solvent included in the developer is 35 MPa^{0.5} or less, and a solubility parameter such that an absolute value of a difference between the solubility parameter and a solubility parameter of the organic solvent included in the rinsing liquid is 5.5 MPa^{0.5} or less.
<16> The method for producing a pattern as described in any one of <9> to <15>,
in which the photocurable composition includes a resin having a CLogP value such that an absolute value of a difference between the CLogP value and a CLogP value of the organic solvent included in the developer is 2 or less, and a CLogP value such that absolute value of a difference between the CLogP value and a CLogP value of the organic solvent included in the rinsing liquid is 0.5 to 3.
<17> A method for manufacturing an optical filter, comprising the method for producing a pattern as described in any one of <1> to <16>.
<18> A method for manufacturing a solid-state imaging element, comprising the method for producing a pattern as described in any one of <1> to <16>.
<19> A method for manufacturing an image display device, comprising the method for producing a pattern as described in any one of <1> to <16>.
<20> A photocurable composition used in the method for producing a pattern as described in any one of <1> to <16>, comprising:
a color material; and
a resin,
in which an acid value of a solid content is 1 to 25 mgKOH/g.
<21> A photocurable composition comprising:
a color material; and
a resin, and
in which an acid value of a solid content is 1 to 25 mgKOH/g, and
the photocurable composition satisfies Condition 1;
Condition 1: in a case where the photocurable composition is applied onto a glass substrate and heated at 100° C. for 2 minutes to form a film, a contact angle of a film surface with respect to pure water after a lapse of 3,000 ms from dropwise addition of 8 μL of pure water onto the film is 70 to 120°.
<22> A film comprising:
a color material; and
a resin, and
in which an acid value of a solid content is 1 to 25 mgKOH/g, and
a contact angle of a film surface with respect to pure water after a lapse of 3,000 ms from dropping of 8 μL of the pure water onto the film is 70° to 120°.

According to the present invention, it is possible to provide a method for producing a pattern, in which a pattern forming property is excellent and generation of residues between the patterns is suppressed, a method for manufacturing an optical filter, a method for manufacturing a solid-state imaging element, and a method for manufacturing an image display device. Furthermore, according to the present invention, it is possible to provide a photocurable composition and a film, each of which can be suitably used in the above-mentioned method for producing a pattern.

### DESCRIPTION OF THE PREFERRED EMBODIMENTS

Hereinafter, the contents of the present invention will be described in detail.

In the present specification, a numerical range expressed using “to” means a range that includes the preceding and succeeding numerical values of “to” as the lower limit value and the upper limit value, respectively.

In citations for a group (atomic group) in the present specification, in a case where the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

In the present specification. “exposure” includes, unless otherwise specified, not only exposure using light but also lithography using particle rays such as electron beams and ion beams. In addition, examples of light used for the exposure generally include actinic rays or radiation such as a bright line spectrum of a mercury lamp, far ultraviolet rays typified by an excimer laser, extreme ultraviolet rays (EUV light), X-rays, and electron beams.

In the present specification, “(meth)acrylate” represents either or both of acrylate and methacrylate. “(meth)acryl” represents either or both of acryl and methacryl, and “(meth)acryloyl” represents either or both of acryloyl and methacryloyl.

In the present specification, a weight-average molecular weight (Mw), a number-average molecular weight (Mn), and a dispersity (also referred to as a molecular weight distribution) (Mw/Mn) of a resin are defined as values in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, and detector: differential refractive index detector) using a GPC apparatus (HLC-81200PC manufactured by Tosoh Corporation).

In the present specification, a total solid content refers to a total mass of the components excluding a solvent from all the components of a composition.

In the present specification, a pigment means a compound that is difficult to dissolve in a solvent. For example, a solubility of the pigment in each of 100 g of water at 23° C. and 100 g of propylene glycol monomethyl ether acetate at 23° C. is preferably 0.1 g or less, and more preferably 0.01 g or less.

In the present specification, a term “step” not only means an independent step but also includes a step which is not clearly distinguished from other steps in a case where an intended action of the step is accomplished.

<Method for Producing Pattern>

The method for producing a pattern of an embodiment of the present invention is a method for producing a pattern, including a step of forming a photocurable composition layer on a support, using a photocurable composition including a color material and a resin and having an acid value of a solid content of 1 to 25 mgKOH/g; a step of patternwise exposing the photocurable composition layer; and a step of treating the photocurable composition layer in an unexposed area using a developer including an organic solvent, thereby performing development.

According to the method for producing a pattern of the embodiment of the present invention, it is possible to form a photocurable composition layer using a photocurable composition having an acid value of a solid content of 1 to 25 mgKOH/g, and treat the photocurable composition layer in an unexposed area using a developer including an organic solvent to efficiently remove the photocurable composition layer in the unexposed area in the organic solvent. Furthermore, since the photocurable composition layer in the exposed area is less likely to be developed with an organic solvent, distortion and the like of a pattern thus formed can be suppressed. Thus, an excellent pattern forming property can be obtained. In addition, since the photocurable composition layer in the unexposed area can be efficiently removed with an organic solvent, generation of development residues (residues among the patterns) can also be efficiently suppressed.

Furthermore, in a case where the photocurable composition layer in the unexposed area was treated with an aqueous alkaline solution, it was necessary to increase the acid value of the solid content in the photocurable composition by, for example, increasing the blending amount of the alkali-soluble resin having a high acid value, but according to the present invention, the acid value of the solid content in the photocurable composition can be lowered, and therefore, it is also possible to increase the color material concentration of the solid content in the photocurable composition, and thus to produce a film having a high color material concentration.

Hereinafter, the method for producing a pattern of the embodiment of the present invention will be described in more detail.

(Photocurable Composition Layer Forming Step)

In the step of forming a photocurable composition layer, a photocurable composition layer is formed on a support, using a photocurable composition including a color material and a resin and having an acid value of a solid content of 1 to 25 mgKOH/g. Details of the photocurable composition will be described later.

The support is not particularly limited and can be appropriately selected depending on the application. Examples of the support include a glass substrate, a substrate for a solid-state imaging element, provided with a solid-state imaging element (light receiving element), and a silicon substrate. In addition, an undercoat layer may be provided on such substrates in order to improve the adhesiveness with an upper layer, prevent the diffusion of substances, or flatten the surface.

As a method for applying the photocurable composition onto the support, a known method can be used. Examples of the method include a dropwise addition method (drop cast); a slit coating method; a spraying method; a roll coating method; a spin coating method (spin coating); a cast coating method; a slit-and-spin method; a pre-wetting method (for example, the method described in JP2009-145395A); various printing methods such as ink jet (for example, an on-demand mode, a piezo mode, and a thermal mode), a jet printing system such as nozzle jet, flexographic printing, screen printing, gravure printing, reverse offset printing, and metal mask printing; a transfer method using a mold or the like; and a nanoimprint method. The application method using ink jet is not particularly limited and examples thereof include a method (in particular, on pp. 115 to 133) shown in “Extension of Use of Ink Jet Infinite Possibilities in Patent” (February 2005, S.B. Research Co., Ltd.) and the methods described in JP2003-262716A, JP2003-185831A, JP2003-261827A, JP2012-126830A, JP2006-169325A, or the like. In addition, with regard to the method for applying the photocurable composition, the methods described in WO2017/030174A or WO2017/018419A can be used, the contents of which are incorporated herein by reference.

After applying the photocurable composition onto the support, further drying (prebaking) may be performed. In a case of performing the prebaking, the prebaking temperature is preferably 150° C. or lower, more preferably 120° C. or lower, and still more preferably 110° C. or lower. The lower limit may be set to, for example, 50° C. or higher, or to 80° C. or higher. The prebaking time is preferably 10 to 3,000 seconds, more preferably 40 to 2,500 seconds, and still more preferably 80 to 2,200 seconds. Drying can be performed using a hot plate, an oven, or the like,

(Exposing Step)

Next, the photocurable composition layer is pattenwise exposed. For example, the photocurable composition layer formed on the support can be patternwise exposed by performing exposure through a mask having a predetermined mask pattern, using an exposure device. Thus, the photocurable composition layer in the exposed area can be cured. As a result, the solubility of the photocurable composition layer in the exposed area in an organic solvent can be reduced.

Examples of the radiation (light) that can be used at the time of exposure include g-rays and i-rays. Further, light at a wavelength of 300 nm or less (preferably light at a wavelength of 180 to 300 nm) can be used. Examples of light at a wavelength of 300 nm or less include KrF rays (wavelength of 248 nm), and ArF rays (wavelength of 193 nm), and the KrF rays (wavelength of 248 nm) are preferable.

Furthermore, light irradiation may be continuously performed for exposure or pulsed irradiation may be performed for exposure (pulse exposure). In addition, the pulse exposure is an exposing method in a mode in which light irradiation and rest are repeated in a short cycle (for example, a millisecond level or lower) to perform exposure. In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, but can be 1 femtosecond (fs) or more, and can be 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50,000,000 W/m² or more, more preferably 100,000,000 W/m² or more, and still more preferably 200,000,000 W/m² or more. Further, the upper limit of the maximum instantaneous illuminance is preferably 1,000,000,000 W/m or less, more preferably 800,000,000 W/m² or less, and still more preferably 500,000,000 W/m² or less. Further, the pulse width is a period of time during which light irradiation is performed in the pulse cycle. Further, the frequency means the number of pulse periods per second. In addition, the maximum instantaneous illuminance is an average illuminance within the time during which light irradiation is performed in the pulse cycle. Further, the pulse cycle is a cycle in which light irradiation and rest in the pulse exposure are performed in one cycle.

The irradiation dose (exposure dose) is, for example, preferably 0.03 to 2.5 J/cm, and more preferably 0.05 to 1.0 J/cm². The oxygen concentration during the exposure can be appropriately selected, and exposure may also be performed in an atmosphere, such as a low-oxygen atmosphere having an oxygen concentration of 19% by volume or less (for example, 15% by volume, 5% by volume, or substantially oxygen-free) or a high-oxygen atmosphere having an oxygen concentration of more than 21% by volume (for example, 22% by volume, 30% by volume, or 50% by volume). Further, the exposure illuminance can be appropriately set, and can be usually selected from a range of 1,000 W/m² to 100,000 W/m² (for example, 5000 W/m², 15,000 W/m², or 35,000 W/m²). Appropriate conditions of each of the oxygen concentration and the exposure illuminance may be combined, and for example, a combination of an oxygen concentration of 10% by volume and an illuminance of 10,000 W/m², a combination of an oxygen concentration of 35% by volume and an illuminance of 20.000 W/m² or the like is available.

(Developing Step)

Next, the unexposed area of the photocurable composition layer is treated and developed using a developer including an organic solvent. As a result, the photocurable composition layer in the unexposed area is removed by the developer to form a pattern (negative tone pattern).

Examples of the organic solvent used in the developer include various organic solvents. Examples thereof include an ester-based solvent, a ketone-based solvent, an alcohol-based solvent, an amide-based solvent, an ether-based solvent, and a hydrocarbon-based solvent. In the present invention, the ester-based solvent means a solvent having an ester group in the molecule. Further, the ketone-based solvent is a solvent having a ketone group in the molecule. The alcohol-based solvent is a solvent having an alcoholic hydroxyl group in the molecule. The amide-based solvent is a solvent having an amido group in the molecule. Further, the ether-based solvent is a solvent having an ether bond in the molecule. Among these, a solvent having a plurality of the above-mentioned functional groups in one molecule exists, but in such the case, the solvent corresponds to any of the solvent species including the functional groups contained in the solvent. For example, diethylene glycol monomethyl ether corresponds to the alcohol-based solvent and the ether-based solvent in the classification. In addition, the hydrocarbon-based solvent is a hydrocarbon-based solvent having no substituent. Hereinaflter, specific examples of the organic solvent will be described.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclopentanone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, propylene glycol monomethyl ether acetate (PGMEA), ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-ethoxybutyl acetate, methyl formate, ethyl formate, butyl formate, propyl formate, ethyl lactate, butyl lactate, propyl lactate, butyl butanoate, methyl 2-hydroxyisobutyrate, isobutyl isobutyrate, and butyl propionate.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, diethylene glycol, and triethylene glycol; and glycol ether-based solvents such as ethylene glycol monomethyl ether, propylene glycol monomethyl ether (also known as 1-methoxy-2-propanol), ethylene glycol monoethyl ether, propylene glycol monoethyl ether, diethylene glycol monomethyl ether, triethylene glycol monoethyl ether and methoxymethyl butanol.

Examples of the ether-based solvent include the glycol ether-based solvent, dioxane, and tetrahydrofuran.

Examples of the amide-based solvent include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include aromatic hydrocarbon-based solvents such as toluene and xylene, and aliphatic hydrocarbon-based solvents such as pentane, hexane, octane, and decane.

In the present invention, it is preferable that the developer includes at least one organic solvent selected from the ketone-based solvent or the alcohol-based solvent for a reason that it has an appropriate polarity, the photosensitive composition layer in the exposed area is less likely to be swollen, and it is easy to obtain an excellent pattern forming property. Further, the developer used in the present invention may include two or more kinds of organic solvents. As a combination of two or more kinds of organic solvents, a combination of the ketone-based solvent and the alcohol-based solvent is preferable for a reason that the photosensitive composition layer in the exposed area is less likely to be swollen, and the photocurable composition layer in the unexposed area has an excellent solubility (developability).

The developer used in the present invention preferably has a moisture content of 10% by mass or less, more preferably 3% by mass or less, and still more preferably 1% by mass or less, and it is particularly preferable that the developer contains substantially no moisture, for a reason that it is easy to obtain more excellent developability. The case where the developer contains substantially no moisture means that the moisture content of the developer is 0.1% by mass or less, preferably 0.01% by mass or less, and more preferably 0% by mass (containing no moisture).

In the developer used in the present invention, the concentration of the organic solvent (in a case where a plurality of kinds thereof are mixed, a total concentration) is preferably 50% by mass or more, more preferably 70% by mass or more, and still more preferably 95% by mass or more, and a case where the developer substantially consists of only the organic solvent is particularly preferable. In addition, a case of consisting substantially of only the organic solvent is intended to include a case of containing a trace amount of a surfactant, an antioxidant, a basic compound, a stabilizer, an antifoaming agent, and the like.

In the developer used in the present invention, the solubility parameter of the organic solvent included in the developer is preferably 18 to 24 MPa^{0.5}. For a reason that the photocurable composition layer in the unexposed area is effectively easily dissolved and removed, the lower limit is preferably 19 MPa^{0.5} or more, more preferably 19.5 MPa^{0.5} or more, and more preferably 20 MPa^{0.5} or more. For a reason that an effect on the photosensitive composition layer of the exposed area can be suppressed, the upper limit is preferably 23 MPa^{0.5} or less, more preferably 22.5 MPa^{0.5} or less, and still more preferably 22 MPa^{0.5} or less. In a case where the developer includes two or more kinds of organic solvents, the above-mentioned solubility parameter of the organic solvents is a solubility parameter in a mixed solution of the two or more kinds of organic solvents calculated from Equation (1).

$${SP}_{ave} = {\sum }_{i = 1}^{n} ( {M}_{i} \times {SP}_{i} ) \qquad ( 1 )$$

SPₐᵥₑ is a solubility parameter in a mixed solution of two or more (n kinds) of organic solvents, Mᵢ is a mass ratio of the organic solvent i in the total amount of the organic solvents (mass of the organic solvent i/mass of all the organic solvents), SPᵢ is a solubility parameter of the organic solvent i, and n is an integer of 2 or more.

In a case where the developer used in the present invention includes two or more kinds of organic solvents, the solubility parameter of each organic solvent is preferably 18 to 24 MPa^{0.5} s for a reason that it is easy to sufficiently secure a solubility of the photocurable composition layer in the unexposed area while suppressing an effect on the photocurable composition layer in the exposed area. The lower limit is preferably 19 MPa^{0.5} or more, more preferably 19.5 MPa^{0.5} or more, and still more preferably 20 MPa^{0.5} or more. The upper limit is preferably 23 MPa^{0.5} or less, more preferably 22.5 MPa^{0.5} or less, and still more preferably 22 MPa^{0.5} or less.

Moreover, in the present specification, a Hansen solubility parameter is used as the solubility parameter of the organic solvent and the solubility parameter of a polymerizable monomer which will be described later. Specifically, a value calculated using Hansen solubility parameter software “HSPiP5.0.09” is used.

In the developer used in the present invention, the ClogP value of the organic solvent included in the developer is preferably 0 to 1. The lower limit is preferably 0.1 or more, and more preferably 0.2 or more for a reason that it is easy to suppress the swelling of the photocurable composition layer in the exposed area. The upper limit is preferably 0.9 or less, and more preferably 0.8 or less for a reason that it is easy to sufficiently secure the solubility of the photocurable composition layer in the unexposed area. In addition, in a case where the developer includes two or more kinds of organic solvents, the CLogP value of the above-mentioned organic solvent is a CLogP value of a mixed solution of the two or more kinds of organic solvents calculated from Equation (2).

$${CLogP}_{ave} = {\sum }_{i = 1}^{n} ( {M}_{i} \times {CLogP}_{i} ) \qquad ( 2 )$$

CLogPₐᵥₑ is a CLogP value in a mixed solution of two or more kinds (n kinds) of organic solvents, Mᵢ is a mass ratio of the organic solvent i in the total amount of the organic solvents (mass of the organic solvent i/mass of all the organic solvents), CLogPᵢ is a CLogP value of the organic solvent i, and n is an integer of 2 or more.

In a case where the developer used in the present invention includes two or more kinds of organic solvents, the CLogP value of each organic solvent is preferably 0 to I for a reason that it is easy to sufficiently secure a solubility of the photocurable composition layer in the unexposed area while suppressing an effect on the photocurable composition layer in the exposed area. The lower limit is preferably 0.1 or more, and more preferably 0.2 or more.

The upper limit is preferably 0.9 or less, and more preferably 0.8 or less. The CLogP value is a calculated value of Log P which is a common logarithm of the partition coefficient P of 1-octanol/water.

In the present specification, the CLogP value is a value determined by predictive calculation using ChemiBioDraw Ultra ver. 13.0.2.3021 (manufactured by Cambridge Soft Corporation).

In the developer used in the present invention, the boiling point of the organic solvent included in the developer is preferably 80° C. to 22° C. The lower limit is preferably 100° C. or higher, more preferably 120° C. or higher, and still more preferably 130° C. or higher. The upper limit is preferably 20° C. or lower, more preferably 180° C. or lower, and still more preferably 160° C. or lower. In a case where the developer includes two or more kinds of organic solvents, the boiling point of the organic solvents is a boiling point of a mixed solution of the two or more kinds of organic solvents calculated from Equation (3).

$${BP}_{ave} = {\sum }_{i = 1}^{n} ( {M}_{i} \times {BP}_{i} ) \qquad ( 3 )$$

BPₐᵥₑ is a boiling point in a mixed solution of two or more kinds (n kinds) of organic solvents. M is a mass ratio of the organic solvent i in the total amount of the organic solvents (mass of the organic solvent i/mass of all the organic solvents), BPᵢ is the boiling point of the organic solvent i, and n is an integer of 2 or more.

In a case where the developer used in the present invention includes two or more kinds of organic solvents, the boiling point of each organic solvent is preferably 50° C. to 300° C., The lower limit is preferably 60° C. or higher, and more preferably 70° C. or higher. The upper limit is more preferably 260° C. or lower, and still more preferably 240° C. or lower.

The organic solvent included in the developer used in the present invention is preferably at least one selected from cyclopentanone, cyclohexanone, isopropyl alcohol, or ethyl lactate, and more preferably cyclopentanone or cyclohexanone for a reason that it is easy to sufficiently secure a solubility of the photocurable composition layer in the unexposed area while suppressing an effect on the photocurable composition layer in the exposed area.

As the treatment method (developing method) with the developer, for example, a method of immersing a support having a photocurable composition layer formed thereon in a bath filled with a developer for a certain period of time (dipping method), a method of performing development by raising a developer on the surface of a photocurable composition layer by surface tension and standing for a certain period of time (puddling method), a method of spraying a developer on the surface of a photocurable composition layer (spraying method), a method of continuously jetting a developer while scanning developer-jetting nozzles at a constant speed on a support rotated at a constant speed (dynamic dispensing method), or the like can be applied, and for a reason that both uniform development and saving of the developer are easily achieved, the puddling method is preferable.

The treatment time (development time) with the developer is preferably 15 to 300 seconds. The lower limit is preferably 30 seconds or more, and more preferably 60 seconds or more. The upper limit is preferably 180 seconds or less, and more preferably 120 seconds or less.

The temperature of the developer is preferably 0° C. to 50° C. The lower limit is preferably 10° C. or higher, and more preferably 20° C. or higher. The upper limit is preferably 40° C. or lower, and more preferably 30° C. or lower.

A drying treatment may be performed after the development. Examples of the drying method include spin drying and spray drying. Among these, the spin drying is preferable since it is possible to perform uniform drying. As a spin drying condition, the rotation speed is preferably 2,000 rpm or more, more preferably 3,000 rpm or more, and still more preferably 4,000 rpm or more. The upper limit is preferably 10,000 rpm or less, more preferably 7,000 rpm or less, and still more preferably 5,000 rpm or less. The drying time is not particularly limited, but is preferably 1 second or more, more preferably 5 seconds or more, and still more preferably 10 seconds or more. The upper limit is not particularly limited, but is preferably 30 seconds or less, more preferably 25 seconds or less, and still more preferably 20 seconds or less.

(Rinsing Step)

The method for producing a pattern of the embodiment of the present invention preferably includes a step of performing rinsing using a rinsing liquid after the step of performing development. As the rinsing liquid, one including at least one selected from water or an organic solvent is used, and it is preferable to perform rinsing using a rinsing liquid including an organic solvent for a reason that the development residues and the like can be more easily reduced.

Examples of the organic solvent used for the rinsing liquid include various organic solvents. Examples thereof include an ester-based solvent, a ketone-based solvent, an alcohol-based solvent, an amide-based solvent, an ether-based solvent, and a hydrocarbon-based solvent. Details thereof include those described in the section of the organic solvent used for the developer.

In the present invention, for a reason that the rinsing liquid easily suppresses a damage to the pattern while reducing the development residues, it is preferable that the rinsing liquid includes at least one organic solvent selected from propylene glycol monomethyl ether acetate, propylene glycol monomethyl ether, cyclohexanone, acetone, or ethyl-3-ethoxypropionate. Moreover, the rinsing liquid used in the present invention may include two or more kinds of organic solvents. As a combination of two or more kinds of organic solvents, a combination of propylene glycol monomethyl ether acetate and propylene glycol monomethyl ether is preferable.

The rinsing liquid used in the present invention preferably has a moisture content of 10% by mass or less, more preferably 3% by mass or less, and still more preferably 1% by mass or less, and it is particularly preferable that the rinsing liquid contains substantially no moisture. The case where the rinsing liquid contains substantially no moisture means that the moisture content of the rinsing liquid is 0.1% by mass or less, and the moisture content is preferably 0.01% by mass or less, and more preferably 0% by mass (containing no water).

In the rinsing liquid used in the present invention, the concentration of the organic solvent (in a case where a plurality of kinds thereof are mixed, a total concentration) is preferably 50% by mass or more, more preferably 70% by mass or more, and still more preferably 95% by mass or more, and a case where the rinsing liquid substantially consists of only the organic solvent is particularly preferable. In addition, a case of consisting substantially of only the organic solvent is intended to include a case of containing a trace amount of a surfactant, an antioxidant, a basic compound, a stabilizer, an antifoaming agent, and the like.

In the rinsing liquid used in the present invention, the solubility parameter of the organic solvent included in the rinsing liquid is preferably 17 to 21 MPa^{0.5}. The lower limit is more preferably is 17.4 MPa^{0.5} or more, preferably 17.7 MPa^{0.5} or more, and more preferably 18 MPa^{0.5} or more. The upper limit is preferably 20 MPa^{0.5} or less, more preferably 19.5 MPa^{0.5} or less, and still more preferably 19 MPa^{0.5} or less.

Furthermore, it is preferable that the solubility parameter of the organic solvent included in the rinsing liquid is smaller than the solubility parameter of the organic solvent included in the developer since it is easy to suppress a damage to the pattern by the rinsing liquid. Moreover, the absolute value of a difference in the solubility parameter between the both is preferably 1.5 MPa^{0.5} or more, more preferably 2.0 MPa^{0.5} or more, and still more preferably 2.5 MPa^{0.5} or more. The upper limit is preferably 4.5 MPa^{0.5} or less, more preferably 4.0 MPa^{0.5} or less, and still more preferably 3.5 MPa^{0.5} or less.

In addition, in a case where the rinsing liquid includes two or more kinds of organic solvents, the solubility parameter of the organic solvents included in the rinsing liquid is a solubility parameter (SPₐᵥₑ) in a mixed solution of the two or more kinds of organic solvents calculated from Equation (1).

In a case where the rinsing liquid used in the present invention includes two or more kinds of organic solvents, the solubility parameter of each organic solvent is preferably 17 to 21 MPa^{0.5}. The lower limit is preferably 17.4 MPa^{0.5} or more, more preferably 17.7 MPa^{0.5} or more, and still more preferably 18 MPa^{0.5} or more. The upper limit is preferably 20 MPa^{0.5} or less, more preferably 19.5 MPa^{0.5} or less, and still more preferably 19 MPa^{0.5} or less.

In the rinsing liquid used in the present invention, the CLogP value of the organic solvent included in the rinsing liquid is preferably 0.3 to 2.0. The lower limit is preferably 0.4 or more, and more preferably 0.5 or more. The upper limit is preferably 1.4 or less, and more preferably 0.9 or less.

Furthermore, it is preferable that the CLogP of the organic solvent included in the rinsing liquid is larger than the CLogP of the organic solvent included in the developer since it is easy to suppress a damage to the pattern by the rinsing liquid. The absolute value of a difference between the two CLogP's is preferably 0.1 or more, more preferably 0.2 or more, and still more preferably 0.3 or more since it is easy to suppress a damage to the pattern by the rinsing liquid. The upper limit is preferably 1.0 or less, more preferably 0.7 or less, and still more preferably 0.5 or less since it is easy to suppress the generation of aggregates caused by reaggregation of the photocurable composition layer dissolved in the developer, and the like. In addition, in a case where the rinsing liquid includes two or more kinds of organic solvents, the CLogP value of the organic solvents included in the rinsing liquid means a CLogP value (CLogPₐᵥₑ) of a mixed solution of the two or more kinds of organic solvents calculated from Equation (2).

In a case where the rinsing liquid used in the present invention includes two or more kinds of organic solvents, the CLogP value of each organic solvent is preferably −0.3 to 3.0. The lower limit is preferably 0.2 or more, more preferably 0.3 or more, still more preferably 0.4 or more, even still more preferably 0.5 or more, and particularly preferably 0.6 or more. The upper limit is preferably 2.4 or less, more preferably 1.8 or less, even more preferably 1.4 or less, and particularly preferably 0.9 or less.

In the rinsing liquid used in the present invention, the boiling point of the organic solvent included in the rinsing liquid is preferably lower than the boiling point of the organic solvent included in the developer, more preferably lower than the boiling point by 10° C. or higher, and still more preferably lower than the boiling point by 20° C. or higher. According to this aspect, it is possible to suppress the remaining of the rinsing liquid on the pattern surface, and it is possible to effectively suppress the generation of defects derived from the residual rinsing liquid. Furthermore, in the rinsing liquid used in the present invention, the boiling point of the organic solvent included in the rinsing liquid is preferably 70° C. to 165° C. The lower limit is preferably 90° C. or higher, more preferably 110° C. or higher, and still more preferably 120° C. or higher. The upper limit is preferably 160° C. or lower, more preferably 155° C. or lower, and still more preferably 150° C. or lower. In addition, in a case where the rinsing liquid includes two or more kinds of organic solvents, the boiling point of the organic solvent included in the rinsing liquid means a boiling point (BPₐᵥₑ) of a mixed solution of the two or more kinds of organic solvents calculated from Equation (3).

In a case where the rinsing liquid used in the present invention includes two or more kinds of organic solvents, the boiling point of each organic solvent is preferably 50° C. to 200° C. The lower limit is preferably 80° C. or higher, more preferably 90° C. or higher, still more preferably 100° C. or higher, even still more preferably 110° C. or higher, and further more preferably 120° C. or higher. The upper limit is preferably 185° C. or lower, more preferably 170° C. or lower, still more preferably 160° C. or lower, even still more preferably 155° C. or lower, and further more preferably 150° C. or lower.

For a reason that both reduction in development residues and suppression of a damage on the pattern are easily achieved, the organic solvent included in the rinsing liquid used in the present invention is preferably at least one selected from propylene glycol monomethyl ether acetate, cyclohexanone, acetone, or ethyl-3-ethoxypropionate, and more preferably at least one selected from propylene glycol monomethyl ether acetate, cyclohexanone, or ethyl-3-ethoxypropionate.

As the treatment method (rinsing method) with the rinsing liquid, for example, a method of immersing a support having a photocurable composition layer formed thereon in a bath filled with a rinsing liquid for a certain period of time (dipping method), a method of spraying a developer on the surface of a photocurable composition layer (spraying method), a method of continuously jetting a developer while scanning developer-jetting nozzles at a constant speed on a support rotated at a constant speed (dynamic dispensing method), or the like can be applied, and the dynamic dispensing method is preferable.

The treating time (rinsing time) with the rinsing liquid is preferably 10 to 120 seconds. The lower limit is preferably 20 seconds or more, and more preferably 30 seconds or more. The upper limit is preferably 90 seconds or less, and more preferably 60 seconds or less.

The temperature of the rinsing liquid is preferably 0° C. to 50° C. The lower limit is preferably 10° C. or higher, and more preferably 20° C. or higher. The upper limit is preferably 40° C. or lower, and more preferably 30° C. or lower.

A drying treatment may be performed after the rinsing. Examples of the drying method include spin drying and spray drying, and the spin drying is preferable. As a spin drying condition, the rotation speed is preferably 2,000 rpm or more, more preferably 3.000 rpm or more, and still more preferably 4,000 rpm or more. The upper limit is preferably 10000 rpm or less, more preferably 7,000 rpm or less, and still more preferably 5,000 rpm or less. The drying time is not particularly limited, but is preferably 5 seconds or more, more preferably 10 seconds or more, and still more preferably 15 seconds or more. The upper limit is not particularly limited, but is preferably 30 seconds or less, more preferably 25 seconds or less, and still more preferably 20 seconds or less.

(Post-Baking Step)

In the method for producing a pattern of the embodiment of the present invention, it is preferable that after the developing step (after performing the rinsing step is after the rinsing step), drying is performed and then a heat treatment (post-baking) is performed. The heating temperature is, for example, preferably 100° C. to 240° C., and more preferably 200° C. to 240° C., The film after the development can be subjected to post-baking continuously or batchwise using a heating unit such as a hot plate, a convection oven (hot-air circulation dryer), and a high-frequency heater under the conditions.

The thickness and the line width of the pattern obtained by the method for producing a pattern of the embodiment of the present invention are not particularly limited. It can be appropriately adjusted according to the use and the purpose. For example, the thickness of the pattern is preferably 20.0 μm or less, more preferably 10.0 μm or less, and still more preferably 5.0 μm or less. The lower limit of the film thickness is preferably 0.1 μm or more, more preferably 0.2 μm or more, and still more preferably 0.3 μm or more. The line width of the pattern is preferably 10.0 μm or less, more preferably 5.0 μm or less, still more preferably 3.0 μm or less, even still more preferably 2.0 μm or less, further more preferably 1.7 μm or less, and particularly preferably 1.5 μm or less. The lower limit is not particularly limited, but can be, for example, 0.1 μm or more.

The use of a pattern obtained by the method for producing a pattern of the embodiment of the present invention is not particularly limited, but can be used for, for example, a solid-state imaging element such as a charge coupled device (CCD) and a complementary metal oxide semiconductor (CMOS), an image display device, or the like. Further, the pattern obtained by the method for producing a pattern of the embodiment of the present invention can be used for a color filter, an infrared cut filter, an infrared transmitting filter, a light shielding film, or the like.

<Photocurable Composition>

Next, the photocurable composition of an embodiment of the present invention will be described. The photocurable composition of the embodiment of the present invention includes a color material and a resin, and has an acid value of the solid content of 1 to 25 mgKOH/g. The photocurable composition of the embodiment of the present invention can be preferably used in the above-mentioned method for producing a pattern of the embodiment of the present invention.

The photocurable composition of the embodiment of the present invention preferably satisfies the following Condition 1.

Condition 1: in a case where the photocurable composition is applied onto a glass substrate and heated at 100° C. for 2 minutes to form a film, a contact angle of a film surface with respect to pure water after a lapse of 3,000 ms from dropwise addition of 8 μL of pure water onto the film is 70° to 120°.

The upper limit of the contact angle under Condition 1 is preferably 110° or less, more preferably 100° or less, and still more preferably 90° or less. The lower limit of the contact angle under Condition 1 is preferably 73° or more, more preferably 76° or more, and still more preferably 79° or more.

The film formed of the photocurable composition that satisfies Condition 1 has a low affinity for water. Further, since the film has a low affinity for water, it has a good affinity for an organic solvent. Therefore, in a case where the photocurable composition layer is formed using the photocurable composition satisfying Condition 1, the unexposed area has a good affinity for the organic solvent and the unexposed area of the photocurable composition layer can be efficiently removed by development.

The acid value of the solid content of the photocurable composition of the embodiment of the present invention is preferably 20 mgKOH/g or less, more preferably 15 mgKOH/g or less, and still more preferably 12 mgKOH/g or less. The lower limit is preferably 2 mgKOH/g or more, and more preferably 3 mgKOH/g or more for a reason of improving the dispersion stability of the color material; easily obtaining a pattern having excellent linearity; or the like.

Further, the amine value of the solid content of the photocurable composition of the embodiment of the present invention is preferably 80 mgKOH/g or less, more preferably 60 mgKOH/g or less, and still more preferably 40 mgKOH/g or less for a reason of improving the dispersion stability of the color material, easily obtaining a pattern having excellent linearity, and the like. The lower limit is preferably 1 mgKOH/g or more, and more preferably 3 mgKOH/g or more.

The photocurable composition of the embodiment of the present invention can be used for a color filter, an infrared transmitting filter, a light shielding film, and the like. Examples of the color filter include a filter having pixels (patterns) of hues selected from red, blue, green, cyan, magenta, and yellow.

Examples of the infrared transmitting filter include a filter which satisfies spectral characteristics with a maximum value of transmittances in the wavelength range of 400 to 640 nm of 20% or less (preferably 15% or less, and more preferably 10% or less) and a minimum value of transmittances in the wavelength range of 1,100 to 1,300 nm of 70% or more (preferably 75% or more, and more preferably 80% or more).

Moreover, it is also preferable that the infrared transmitting filter is a filter satisfying any of the following spectral characteristics (1) to (4).

(1): A filter in which the maximum value of transmittances in the wavelength range of 400 to 640 nm is 20% or less (preferably 15% or less, and more preferably 10% or less) and the minimum value of transmittances in the wavelength range of 800 to 1,300 nm is 70% or more (preferably 75% or more, and more preferably 80% or more).

(2): A filter in which the maximum value of transmittances in the wavelength range of 400 to 750 nm is 20% or less (preferably 15% or less, and more preferably 10% or less) and the minimum value of transmittances in the wavelength range of 900 to 1,300 nm is 70% or more (preferably 75% or more, and more preferably 80% or more).

(3): A filter in which the maximum value of transmittances in the wavelength range of 400 to 830 nm is 20% or less (preferably 15% or less, and more preferably 10% or less) and the minimum value of transmittances in the wavelength range of 1,000 to 1,300 nm is 70% or more (preferably 75% or more, and more preferably 80% or more).

(4): A filter in which the maximum value of transmittances in the wavelength range of 400 to 950 nm is 20% or less (preferably 15% or less, and more preferably 10% or less) and the minimum value of transmittances in the wavelength range of 1,100 to 1,300 nm is 70% or more (preferably 75% or more, and more preferably 80% or more).

In a case where the photocurable composition of the embodiment of the present invention is used as a composition for an infrared transmitting filter, it is preferable that the photocurable composition of the embodiment of the present invention satisfies spectral characteristics with Amin/Bmax of S or more, in which the Amin/Bmax is a ratio to a minimum value Amin of the absorbance in the wavelength range of 400 to 640 nm to a maximum value Bmax of the absorbance in the wavelength range of 1,100 to 1,300 nm. Amin/Bmax is more preferably 7.5 or more, still more preferably 15 or more, and particularly preferably 30 or more.

An absorbance Aλ at a certain wavelength λ is defined by Equation (1).

Aλ=−log(Tλ/100) (1)

Aλ is an absorbance at a wavelength λ and Tλ represents a transmittance (%) at the wavelength λ.

In the present invention, a value of the absorbance may be a value measured in the state of a solution or a value in terms of a film which is formed using the photocurable composition. In a case where the absorbance is measured in the state of a film, it is preferable that the absorbance is measured using a film prepared by applying the photocurable composition onto a glass substrate using a method such as spin coating such that the thickness of the dried film is a predetermined value; and drying the applied composition at 100° C. for 120 seconds using a hot plate.

In a case where the photocurable composition of the embodiment of the present invention is used as a composition for an infrared transmitting filter, it is more preferable that the photocurable composition of the embodiment of the present invention satisfies any of the following spectral characteristics (11) to (14).

(11): The ratio of the minimum value Amin1 in an absorbance in the wavelength range of 400 to 640 nm to the maximum value Bmax1 in an absorbance in the wavelength range of 800 to 1,300 nm, Amin1/Bmax1, is 5 or more, preferably 7.5 or more, more preferably 15 or more, and still more preferably 30 or more. According to this aspect, it is possible to form a filter capable of shielding a light in the wavelength range of 400 to 640 nm and transmitting a light at a wavelength of 720 nm or more.

(12): The ratio of the minimum value Amin2 in an absorbance in the wavelength range of 400 to 750 nm to the maximum value Bmax2 in an absorbance in the wavelength range of 900 to 1,300 nm, Amin2/Bmax2, is 5 or more, preferably 7.5 or more, more preferably 15 or more, and still more preferably 30 or more. According to this aspect, it is possible to form a filter capable of shielding a light in the wavelength range of 400 to 750 nm and transmitting a light at a wavelength of 850 nm or more.

(13): The ratio of the minimum value Amin3 in an absorbance in the wavelength range of 400 to 850 nm to the maximum value Bmax3 in an absorbance in the wavelength range of 1,000 to 1,300 nm, Amin3/Bmax3, is 5 or more, preferably 7.5 or more, more preferably 15 or more, and still more preferably 30 or more. According to this aspect, it is possible to form a filter capable of shielding a light in the wavelength range of 400 to 850 nm and transmitting a light at a wavelength of 940 nm or more.

(14): The ratio of the minimum value Amin4 in an absorbance in the wavelength range of 400 to 950 nm to the maximum value Bmax4 in an absorbance in the wavelength range of 1,100 to 1,300 nm, Amin4/Bmax4, is 5 or more, preferably 7.5 or more, more preferably 15 or more, and still more preferably 30 or more. According to this aspect, it is possible to form a filter capable of shielding a light in the wavelength range of 400 to 950 nm and transmitting a light at a wavelength of 1,040 nm or more.

Hereinafter, the respective components used in the photocurable composition of the embodiment of the present invention will be described.

<<Color Material>>

The photocurable composition of the embodiment of the present invention includes a color material. Examples of the color material include achromatic colorant, a black colorant, and an infrared absorbing coloring agent. The color material used in the photocurable composition of the embodiment of the present invention preferably includes at least the chromatic colorant.

(Chromatic Colorant)

Examples of the chromatic colorant include a red colorant, a green colorant, a blue colorant, a yellow colorant, a violet colorant, and an orange colorant. The chromatic colorant may be either a pigment or a dye. The pigment is preferable for a reason that it is less likely to remain as a residue after being removed together with a resin such as a dispersant upon development. It is preferable that an average particle diameter (r) of the pigment satisfies preferably 20 nm≤r≤300 nm, more preferably 25 nm≤r≤250 nm, and still more preferably 30 nm≤r≤200 nm. The “average particle diameter” as mentioned herein means an average particle diameter for secondary particles to which primary particles of the pigment are aggregated. In addition, with regard to a particle size distribution of the secondary particles of the pigment (hereinafter simply referred to as “particle si distribution”) which can be used, secondary particles having a particle diameter of (average particle diameter±100 nm) account for preferably 70% by mass or more, and more preferably 80% by mass or more in the entire pigment.

The pigment is preferably an organic pigment. Examples of the organic pigment include the following pigments.

Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 131, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 231, and the like (all of which are yellow pigments),

C.I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments),

C.I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 32:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 17, 179, 184, 185, 187, 188, 190, 200, 202, 206, 207, 208, 209, 210, 216, 220, 224, 226, 242, 246, 254, 255, 264, 270, 272, 279, and the like (all of which are red pigments),

C. I. Pigment Green 7, 10, 36, 37, 58, 59, 62, 63, and the like (all of which are green pigments),

C. I. Pigment Violet 1, 19, 23, 27, 32, 37, 42, and the like (all of which are violet pigments),

C. I. Pigment Blue 1, 2, 15, 15:1, 15:2, 15:3, 15:4, 15:6, 16, 22, 60, 64, 66, 79, 80, and the like (all of which are blue pigments).

These organic pigments can be used alone or in combination of two or more kinds thereof.

Furthermore, as the yellow pigment, a metal azo pigment including at least one anion selected from an azo compound represented by Formula (I) or an azo compound having a tautomeric structure thereof; two or more metal ions; and a melamine compound can also be used.

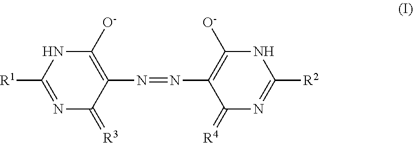

In the formula, R¹ and R² are each independently —OH or —NR⁵R⁶, R³ and R⁴ are each independently ═O or ═NR⁷, and R⁵ to R⁷ are each independently a hydrogen atom or an alkyl group. The alkyl group represented by each of R⁵ to R⁷ preferably has 1 to 10 carbon atoms, more preferably has 1 to 6 carbon atoms, and still more preferably has 1 to 4 carbon atoms. The alkyl group may be linear, branched, or cyclic, preferably linear or branched, and more preferably linear. The alkyl group may have a substituent. The substituent is preferably a halogen atom, a hydroxyl group, an alkoxy group, a cyano group, or an amino group.

In Formula (I), R¹ and R² are preferably —OH. Further, R³ and R⁴ are preferably ═O.

The melamine compound in the metal azo pigment is preferably a compound represented by Formula (II).

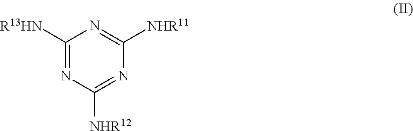

In the formula, R¹¹ to R¹³ are each independently a hydrogen atom or an alkyl group. The number of carbon atoms of the alkyl group is preferably 1 to 10, more preferably 1 to 6, and still more preferably 1 to 4. The alkyl group may be linear, branched, or cyclic, preferably linear or branched, and more preferably linear. The alkyl group may have a substituent. The substituent is preferably a hydroxyl group. It is preferable that at least one of R¹¹, . . . , or R¹³ is a hydrogen atom, and it is more preferable that all of R¹¹ to R¹³ are hydrogen atoms.

The metal azo pigment is preferably a metal azo pigment in an aspect including at least one anion selected from the azo compound represented by Formula (I) or the azo compound having a tautomeric structure thereof; metal ions including at least Zn²⁺ and Cu²⁺; and a melamine compound. In this aspect, the total amount of Zn²⁺ and Cu²⁺ is preferably 95% to 100% by mole, more preferably 98% to 100% by mole, still more preferably 99.9% to 100% by mole, and particularly preferably 100% by mole, with respect to 1 mole of all the metal ions of the metal azo pigment. The molar ratio of Zn²⁺ to Cu²⁺ in the metal azo pigment is preferably Zn²⁺:Cu²⁺=199:1 to 1:15, more preferably 19:1 to 1:1, and still more preferably 9:1 to 2:1. Furthermore, in this aspect, the metal azo pigment may further include a divalent or trivalent metal ion other than Zn²⁺ and Cu²⁺ (hereinafter also referred to as a metal ion Mel). Examples of the metal ion Mel include Ni²⁺, Al³⁺, Fe²⁺, Fe³⁺, Co²⁺, Co³⁺, La³⁺, Ce³⁺, Pr³⁺, Nd²⁺, Nd³⁺, Sm²⁺, Sm³⁺, Eu²⁺, Eu³⁺, Gd³⁺, Tb³⁺, Dy³⁺, Ho³⁺, Yb²⁺, Yb³⁺, Er³⁺, Tm³⁺, Mg²⁺, Ca²⁺, Sr²⁺, Mn²⁺, Y³⁺, Sc³⁺, Ti²⁺, Ti³⁺, Nb³⁺, Mo²⁺, Mo³⁺, V²⁺, V³⁺, Zr²⁺, Zr³⁺, Cd²⁺, Cr²⁺, Pb²⁺, and Ba²⁺; at least one selected from Al³⁺, Fe²⁺, Fe³⁺, Co²⁺, Co³⁺, La³⁺, Ce³⁺, Pr³⁺, Nd³⁺, Sm³⁺, Eu³⁺, Gd³⁺, Tb³⁺, Dy³⁺, Ho³⁺, Yb³⁺, Er³⁺, Tm³⁺, Mg²⁺, Ca²⁺, Sr²⁺, Mn²⁺, or Y³⁺ is preferable; at least one selected from Al³⁺, Fe²⁺, Fe³⁺, Co²⁺, Co³⁺, La³⁺, Ce³⁺, Pr³⁺, Nd³⁺, Sm³⁺, Tb³⁺, Ho³⁺, or Sr²⁺ is more preferable; and at least one selected from Al³⁺, Fe²⁺, Fe³⁺, Co²⁺, or Co³⁺ is particularly preferable. The content of the metal ion Mel is preferably 5% by mole or less, more preferably 2% by mole or less, and still more preferably 0.1% by mole or less, with respect to 1 mole of all the metal ions of the metal azo pigment.

With regard to the metal azo pigment, reference can be made to the descriptions in paragraph Nos. 0011 to 0062 and 0137 to 0276 of JP2017-171912A, paragraph Nos. 0010 to 0062 and 0138 to 0295 of JP2017-171913A, paragraph Nos. 0011 to 0062 and 0139 to 0190 of JP2017-171914A, and paragraph Nos. 0010 to 0065 and 0142 to 0222 of JP2017-171915A, the contents of which are incorporated herein by reference.

In addition, as the red pigment, a compound having a structure where an aromatic ring group to which a group with an oxygen atom, a sulfur atom, or a nitrogen atom being bonded to an aromatic ring is introduced is bonded to a diketopyrrolopyrrole skeleton can also be used. As such a compound, a compound represented by Formula (DPP1) is preferable, and a compound represented by Formula (DPP2) is more preferable.

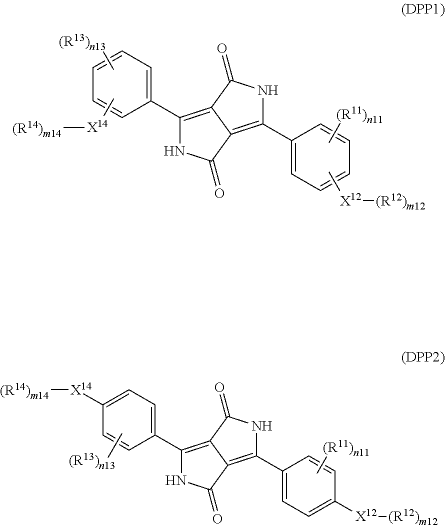

In the formulae, R¹¹ and R¹³ each independently represent a substituent; R¹² and R¹⁴ each independently represent a hydrogen atom, an alkyl group, an aryl group, or a heteroaryl group; n11 and n13 each independently represent an integer of 0 to 4; X¹² and X¹⁴ each independently represent an oxygen atom, a sulfur atom, or a nitrogen atom; in a case where X¹² is the oxygen atom or the sulfur atom, m12 represents 1; in a case where X¹² is the nitrogen atom, m12 represents 2; in a case where X¹⁴ is the oxygen atom or the sulfur atom, m14 represents 1; and in a case where X¹⁴ is the nitrogen atom, m14 represents 2. Preferred specific examples of the substituent represented by each of R¹¹ and R¹³ include an alkyl group, an aryl group, a halogen atom, an acyl group, an alkoxycarbonyl group, an aryloxycarbonyl group, a hetermeryloxycarbonyl group, an smido group, a cyano group, a nitro group, a trifluoromethyl group, a sulfoxide group, and a sulfo group.

Furthermore, as the green pigment, a halogenated zinc phthalocyanine pigment having 10 to 14 halogen atoms on average, 8 to 12 bromine atoms on average, and 2 to 5 chlorine atoms on average in one molecule can also be used. Specific examples thereof include the compounds described in WO2015/118720A.

Moreover, an aluminum phthalocyanine compound having a phosphorus atom can also be used as the blue pigment. Specific examples thereof include the compounds described in paragraphs 0022 to 0030 of JP2012-247591 A and paragraph 0047 of JP2011-157478A.

The dye is not particularly limited and a known dye can be used. Examples thereof include a pyrazole azo-based dye, an anilinoazo-based dye, a triarylmethane-based dye, an anthraquinone-based dye, an anthrapyridone-based dye, a benzylidene-based dye, an oxonol-based dye, a pyrazolotriazole azo-based dye, a pyridone azo-based dye, a cyanine-based dye, a phenothiazine-based dye, a pyrrolopyrazole azomethine-based dye, a xanthene-based dye, a phthalocyanine-based dye, a benzopyran-based dye, an indigo-based dye, and a pyrromethene-based dye. Further, a multimer of such a dye may be used. In addition, the dyes described in JP2015-028144A and JP2015-034966A can also be used.

As the yellow colorant, the coloring agents described in WO2012/128233A and JP2017-201003A can be used. Further, as the red colorant, the coloring agents described in WO2012/102399A, WO2012/117965A, and JP2012-229344A can be used. Moreover, as the green colorant, the coloring agents described in WO2012/102395A can be used. In addition, the salt-forming dyes described in WO2011/037195A can also be used.

(Black Colorant)

Examples of the black colorant include inorganic black colorants such as carbon black, metal oxynitrides (titanium black and the like), and metal nitrides (titanium nitride and the like); and organic black colorants such as a bisbenofuranone compound, an azomethine compound, a perylene compound, and an azo compound. The organic black colorant is preferably the bisbenzofuranone compound or the perylene compound. Examples of the bisbenzofuranone compound include those described in JP2010-534726A, JP2012-515233A, and JP2012-515234A, and are available as, for example, “Irgaphor Black” manufactured by BASF Corporation. Examples of the perylene compound include C. I. Pigment Black 31 and 32. Examples of the azomethine compound include those described in JP1989-170601A (JP-H01-170601A), JP1990-034664A (JP-H02-034664A), and the like, and are available as, for example, “CHROMOFINE BLACK A1103” manufactured by Dainichiseika Color & Chemicals Mfg. Co., Ltd. The bisbenzofuranone compound is preferably a compound represented by any of the following formulae or a mixture thereof.

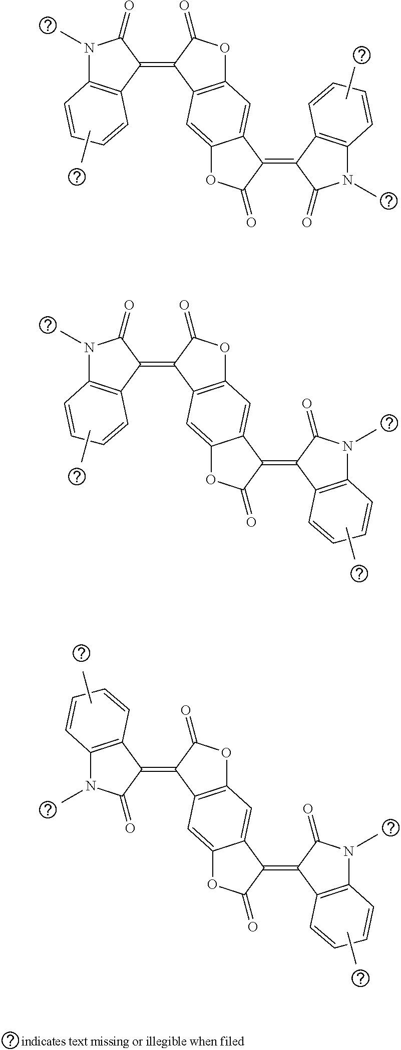

In the formulae, R¹ and R² each independently represent a hydrogen atom or a substituent, R³ and R⁴ each independently represent a substituent, and a and b each independently represent an integer of 0 to 4; in a case where a is 2 or more, a plurality of R³'s may be the same as or different from each other and the plurality of R³'s may be bonded to each other to form a ring; and in a case where b is 2 or more, a plurality of R⁴'s may be the same as or different from each other and the plurality of R⁴'s may be bonded to each other to form a ring.

The substituent represented by each of R¹ to R⁴ represents a halogen atom, a cyano group, a nitro group, an alkyl group, an alkenyl group, an alkynyl group, an aralkyl group, an aryl group, a heteroaryl group, —OR³⁰¹, —COR³⁰², —COOR³⁰³, —OCOR³⁰⁴, —NR³⁰⁵R³⁰⁶, —NHCOR³⁰⁷, —CONR³⁰⁸R³⁰⁹, —NHCONR³¹⁰R³¹¹, —NHCOOR³¹², —SR³¹³, —SO₂R³¹⁴, —SO₂OR³¹⁵, —NHSO₂R³¹⁶, or —SO₂NR³¹⁷R³¹⁸, and R³⁰¹ to R³¹⁸ each independently represent a hydrogen atom, an alkyl group, an alkenyl group, an alkynyl group, an aryl group, or a heteroaryl group.

With regard to the details of the bisbenzofuranone compounds, reference can be made to the description in paragraph Nos. 0014 to 0037 of JP2010-534726A, the contents of which are incorporated herein by reference.

(Infrared Absorbing Coloring Agent)

The infrared absorbing coloring agent is preferably a compound having a maximum absorption wavelength in the wavelength range of 700 to 1,300 nm, and more preferably a compound having a maximum absorption wavelength in the wavelength range of 700 to 1,000 nm. The infrared absorbing coloring agent may be either a pigment or a dye.

In the present invention, as the infrared absorbing coloring agent, a compound having a π-conjugated plane including a monocyclic or fused aromatic ring can be preferably used. The number of atoms other than hydrogen constituting a π-conjugated plane contained in the infrared absorbing coloring agent is preferably 14 or more, more preferably 20 or more, still more preferably 25 or more, and particularly preferably 30 or more. The upper limit is, for example, preferably 80 or less, and more preferably 50 or less. The π-conjugated plane contained in the infrared absorbing coloring agent preferably includes two or more monocyclic or fused aromatic rings, more preferably includes three or more monocyclic or fused aromatic rings, still more preferably includes four or more monocyclic or fused aromatic rings, and particularly preferably includes five or more monocyclic or fused aromatic rings. The upper limit is preferably 100 or less, more preferably 50 or less, and still more preferably 30 or less. Examples of the above-mentioned aromatic ring include a benzene ring, a naphthalene ring, a pentalene ring, an indene ring, an azulene ring, a heptalene ring, an indacene ring, a perylene ring, a pentacene ring, a quaterrylene ring, an acenaphthene ring, a phenanthrene ring, an anthracene ring, a naphthacene ring, a chrysene ring, a triphenylene ring, a fluorene ring, a pyridine ring, a quinoline ring, an isoquinoline ring, an imidazole ring, a benzimidazole ring, a pyrazole ring, a thiazole ring, a benzothiazole ring, a triazole ring, a benzotriazole ring, an oxazole ring, a benzoxazole ring, an imidazoline ring, a pyrazine ring, a quinoxaline ring, a pyrimidine ring, a quinazoline ring, a pyridazine ring, a triazine ring, a pyrrole ring, an indole ring, an isoindole ring, a carbazole ring, and a fused ring having such the ring.

As the infrared absorbing coloring agent, at least one compound selected from a pyrrolopyrrole compound, a cyanine compound, a squarylium compound, a phthalocyanine compound, a naphthalocyanine compound, a quaterrylene compound, a merocyanine compound, a croconium compound, an oxonol compound, a diimmonium compound, a dithiol compound, a triarylmethane compound, a pyrromethene compound, an azomethine compound, an anthraquinone compound, or a dibenzofuranone compound is preferable; at least one compound selected from the pyrrolopyrrole compound, the cyanine compound, the squarylium compound, the phthalocyanine compound, the naphthalocyanine compound, or the diimmonium compound is more preferable; at least one selected from the pyrrolopyrrole compound, the cyanine compound, or the squarylium compound is still more preferable; and the pyrrolopyrrole compound is particularly preferable.

Examples of the pyrrolopyrrole compound include the compounds described in paragraph Nos. 0016 to 0058 of JP2009-263614A, the compounds described in paragraph Nos. 0037 to 0052 of JP2011-068731 A, and the compounds described in paragraph Nos. 0010 to 0033 of WO205/166873A, the contents of which are incorporated herein by reference.

Examples of the squarylium compound include the compounds described in paragraph Nos. 0044 to 0049 of JP2011-208101 A, the compounds described in paragraph Nos. 0060 and 0061 of JP6065169B, the compounds described in paragraph No. 0040 of WO2016/181987A, the compounds described in WO2013/133099A, the compounds described in WO2014/088063A, the compounds described in JP2014-126642A, the compounds described in JP206-146619A, the compounds described in JP2015-176046A, the compounds described in JP2017-02531IA, the compounds described in WO2016/154782A, the compounds described in JP5884953, the compounds described in JP6036689B, the compounds described in JP5810604B, the compounds described in JP2017-068120A, the contents of which are incorporated herein by reference.

Examples of the cyanine compound include the compounds described in paragraph Nos. 0044 to 0045 of JP2009-108267A, the compounds described in paragraph Nos. 026 to 0030 of JP2002-194040A, the compounds described in JP2015-172004A, the compounds described in JP2015-172102A, the compounds described in JP2008-088426A, and the compounds described in JP2017-031394A, the contents of which are incorporated herein by reference.

Examples of the diimmonium compound include the compounds described in JP2008-528706A, the contents of which are incorporated herein by reference. Examples of the phthalocyanine compound include the compounds described in paragraph No. 0093 of JP2012-077153A, the oxytitanium phthalocyanine described in JP2006-343631A, and the compounds described in paragraph Nos. 0013 to 0029 of JP2013-195480A, the contents of which are incorporated herein by reference. Examples of the naphthalocyanine compound include the compounds described in paragraph No. 0093 of JP2012-077153A, the contents of which are incorporated herein by reference.

In the present invention, as the infrared absorbing coloring agent, a commercially available product can also be used. Examples thereof include SDO-C33 (manufactured by Arimoto Chemical Co., Ltd.); EXCOLOR IR-14, EXCOLOR IR-10A, EXCOLOR TX-EX-801B, or EXCOLOR TX-EX-805K (manufactured by Nippon Shokubai Co., Ltd.), Shigenox NIA-8041, Shigenox NIA-8042, Shigenox NIA-814, Shigenox NIA-820, or Shigenox NIA-839 (manufactured by Hakkol Chemical Co., Ltd.), Epolite V-63, Epolight 3801, or Epolight3036 (manufactured by Epolin Inc.), PRO-JET 825LDI (manufactured by Fujifilm Corporation). NK-3027 or NK-5060 (manufactured by Hayashibara Co., Ltd.), and YKR-3070 (manufactured by Mitsui Chemicals, Inc.).

The content of the color material in the total solid content of the photocurable composition is preferably 40% by mass or more, more preferably 50% by mass or more, still more preferably 55% by mass or more, and particularly preferably 60% by mass or more, from the viewpoint of reducing the thickness of a film thus obtained. In a case where the content of the color material is 40% by mass or more, it is easy to form a thin film having good spectral characteristics. From the viewpoint of a film forming property, the upper limit is preferably 80% by mass or less, more preferably 75% by mass or less, and still more preferably 70% by mass or less.

The color material used in the photocurable composition of the embodiment of the present invention preferably includes at least one selected from a chromatic colorant or a black colorant. Moreover, the content of the chromatic colorant and the black colorant in the total mass of the color material is preferably 30% by mass or more, more preferably 50% by mass or more, and still more preferably 70% by mass or more. The upper limit can be 100% by mass, or can be 90% by mass or less.

Furthermore, it is preferable that the color material used in the photocurable composition of the embodiment of the present invention includes at least a green colorant. In addition, the content of the green colorant agent in the total mass of the color material is preferably 30% by mass or more, more preferably 40% by mass or more, and still more preferably 50% by mass or more. The upper limit may be 100% by mass, and may be 75% by mass or less.

For the color material used in the photocurable composition of the embodiment of the present invention, the content of the pigment in the total mass of the color material is preferably 50% by mass or more, more preferably 70% by mass or more, and still more preferably 90% by mass or more. In a case where the content of the pigment in the total mass of the color material is within the range, a film in which spectral fluctuation due to heat is suppressed can be easily obtained.

In a case where the photocurable composition of the embodiment of the present invention is used as a composition for a color filter, the content of the chromatic colorant in the total solid content of the photocurable composition is preferably 40% by mass or more, more preferably 50% by mass or more, still more preferably 55% by mass or more, and particularly preferably 60% by mass or more. Moreover, the content of the chromatic colorant in the total mass of the color material is preferably 25% by mass or more, more preferably 45% by mass or more, and still more preferably 65% by mass or more. The upper limit may be 100% by mass, and may be 75% by mass or less. Furthermore, the color material preferably includes at least a green colorant. In addition, the content of the green colorant in the total mass of the color material is preferably 35% by mass or more, more preferably 45% by mass or more, and still more preferably 55% by mass or more. The upper limit can be 100% by mass, or can be 80% by mass or less.

In a case where the photocurable composition of the embodiment of the present invention is used as a composition for forming a light shielding film, the content of the black colorant (preferably an inorganic black colorant) in the total solid content of the photocurable composition is preferably 40% by mass or more, more preferably 50% by mass or more, still more preferably 55% by mass or more, and particularly preferably 60% by mass or more. In addition, the content of the black colorant agent in the total mass of the color material is preferably 30% by mass or more, more preferably 50% by mass or more, and still more preferably 70% by mass or more. The upper limit can be 100% by mass, or can be 90% by mass or less.

In a case where the photocurable composition of the embodiment of the present invention is used as a composition for an infrared transmitting filter, the color material used in the present invention preferably satisfies at least one of the following requirements (1), . . . , or (3).
(1): Two or more kinds of chromatic colorants are included, and the two or more kinds of chromatic colorants are combined to form black. It is preferable to form black by combination of two or more kinds of colorants selected from a red colorant, a blue colorant, a yellow colorant, a violet colorant, or a green colorant.
(2): An organic black colorant is included.
(3): (1) or (2), in which an infrared absorbing coloring agent is further included.

Preferred examples of the combination of the aspects of (1) include the following ones.
(1-1) An aspect in which a red colorant and a blue colorant are contained.
(1-2) An aspect in which a red colorant, a blue colorant, and a yellow colorant are contained.
(1-3) An aspect in which a red colorant, a blue colorant, a yellow colorant, and a violet colorant are contained.
(1-4) An aspect in which a red colorant, a blue colorant, a yellow colorant, a violet colorant, and a green colorant are contained.
(1-5) An aspect in which a red colorant, a blue colorant, a yellow colorant, and a green colorant are contained.
(1-6) An aspect in which a red colorant, a blue colorant, and a green colorant are contained.
(1-7) An aspect in which a yellow colorant and a violet colorant are contained.

In the aspect of (2), it is also preferable that a chromatic colorant is further contained. By using the organic black colorant and the chromatic colorant in combination, it is easy to obtain excellent spectral characteristics. Examples of the chromatic colorant which is used in combination with the organic black colorant include a red colorant, a blue colorant, and a violet colorant, with the red colorant or the blue colorant being preferable. These may be used alone or in combination of two or more kinds thereof. In addition, regarding a mixing ratio between the chromatic colorant and the organic black colorant, the amount of the chromatic colorant is preferably 10 to 200 parts by mass, and more preferably 15 to 150 parts by mass, with respect to 100 parts by mass of the organic black colorant.

In the aspect of (3), the content of the infrared absorbing coloring agent in the total mass of the color material is preferably 5% to 40% by mass. The upper limit is preferably 30% by mass or less, and more preferably 25% by mass or less. The lower limit is preferably 10% by mass or more, and more preferably 15% by mass or more.

<<Resin>>

The photocurable composition of the embodiment of the present invention contains a resin. In the present invention, the resin means an organic compound other than the color material, which has a molecular weight of 3,000 or more. The resin is formulated, for example, in applications for dispersing particles such as a pigment in a composition, or in applications as a binder. Incidentally, a resin which is used for dispersing particles such as a pigment is also referred to as a dispersant. However, such applications of the resin are only exemplary, and the resin can also be used for other purposes, in addition to such applications.

The weight-average molecular weight (Mw) of the resin is preferably 3,000 to 2,000,000. The upper limit is preferably 1,000,000 or less, and more preferably 500,000 or less. The lower limit is preferably 4,000 or more, and more preferably 5,000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, and a styrene resin. Among those, the (meth)acrylic resin is preferable for a reason that it is easy to obtain more excellent developability.

The solubility parameter of the resin is preferably 18 to 24 MPa^{0.5}. The lower limit is preferably 19 MPa^{0.5} or more, and more preferably 20 MPa^{0.5} or more. The upper limit is preferably 23 MPa^{0.5} or less, and more preferably 22 MPa^{0.5} or less. In a case where the solubility parameter of the resin is within the range, the photosensitive composition layer in the unexposed area is easily removed by a developer and an excellent pattern forming property is easily obtained. Furthermore, it is easy to more effectively suppress the generation of development residues. In addition, the solubility parameter of the resin is a value calculated by an OKITSU method.

Moreover, the CLogP value of the resin is preferably 0 to 10. The lower limit is preferably 1 or more, and more preferably 2 or more. The upper limit is preferably 8 or less, and more preferably 6 or less. In a case where the CLogP value of the resin is within the range, the photosensitive composition layer in the unexposed area is easily removed by the developer, and an excellent pattern forming property is easily obtained. Furthermore, it is easy to more effectively suppress the generation of development residues. In the present specification, the ClogP value of the resin is a value calculated as follows. In a case where the resin is constituted with repeating units D1, D2, . . . , Dn, the ClogP values of the monomers corresponding to the repeating units D1, D2, . . . , Dn are defined as ClogP1, ClogP2, . . . , ClogPn, respectively, and the molar fractions of the repeating units D1, D2, . . . , Dn in the resin were defined as ω1, ω2, . . . , ωn, respectively, the ClogP value was calculated by the following equation.

C log P value of resin=Σ[(ω1×C log P1)+(ω2×C log P2)+ . . . (ωn−C log Pn)]

Moreover, the ClogP values (ClogP1, ClogP2, . . . , ClogPn) of the monomers corresponding to the repeating units D1, D2, . . . , Dn are values determined by predictive calculation using ChemiBioDraw Ultra ver. 13.0.2.3021 (manufactured by Cambridge Soft Corporation).

In the present invention, a resin having an acid group may be used as the resin. Examples of the acid group include a carboxyl group, a phosphoric acid group, a sulfo group, and a phenolic hydroxyl group, with the carboxyl group being preferable.

The resin having an acid group preferably includes repeating units having an acid group in a side chain, and more preferably includes 5% to 80% by mole of the repeating units having an acid group in a side chain in all the repeating units of the resin. The upper limit of the content of the repeating units having an acid group in a side chain is preferably 70% by mole or less, and more preferably 50% by mole or less. The lower limit of the content of the repeating units having an acid group in a side chain is preferably 10% by mole or more, and more preferably 20% by mole or more.

With regard to the resin having an acid group, reference can be made to the description in paragraph Nos. 0558 to 0571 of JP2012-208494A (pararaph Nos. 0685 to 0700 of the corresponding US2012/0235099A, the contents of which are incorporated herein by reference.

In addition, it is also possible to use the copolymers (B) described in paragraph Nos. 0029 to 0063 of JP2012-032767A and the alkali-soluble resins used in Examples of the publication; the binder resins described in paragraph Nos. 0MS to 0098 of JP2012-208474A and the binder resins used in Examples of the publication; the binder resins described in paragraph Nos. 0022 to 0032 of JP2012-137531A and the binder resins in Examples of the publication; the binder resins described in paragraph Nos. 0132 to 0143 of JP2013-024934A and the binder resins used in Examples of the publication; the binder resins described in paragraph Nos. 0092 to 0098 of JP2011-242752A and used in Examples; or the binder resins described in paragraph Nos. 0030 to 0072 of JP2012-032770A. The contents of these publications are incorporated herein by reference.

The acid value of the resin having an acid group is preferably 5 to 200 mgKOWg. The lower limit is more preferably 10 mgKO/g or more, still more preferably 15 mgKOH/g or more, and particularly preferably 20 mgKOH/g or more. The upper limit is more preferably 150 mgKOH/g or less, and more preferably 100 mgKOWg or less.

The weight-average molecular weight (Mw) of the resin having an acid group is preferably 5,000 to 100,000. The number-average molecular weight (Mn) of the resin having an acid group is preferably 1.000 to 20,000.

It is also preferable that the resin used in the present invention is a resin including a repeating unit derived from a monomer component including a compound represented by Formula (ED1) and/or a compound represented by Formula (ED2) (hereinafter these compounds may be referred to as “ether dimers” in some cases).

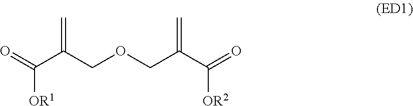

In Formula (ED1), R¹ and R² each independently represent a hydrogen atom or a hydrocarbon group having 1 to 25 carbon atoms, which may have a substituent

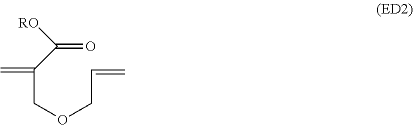

In Formula (ED2), R represents a hydrogen atom or an organic group having 1 to 30 carbon atoms. With regard to the details of Formula (ED2), reference can be made to the description in JP2010-168539A, the contents of which are incorporated herein by reference.

With regard to specific examples of the ether dimer, reference can be made to the description in paragraph No. 0317 of P2013-029760A, the contents of which are incorporated herein by reference.

The resin used in the present invention is also preferably a resin including a repeating unit derived from a compound represented by Formula (X).

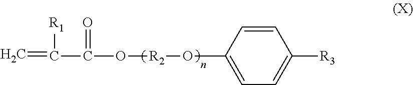

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms, which may include a benzene ring. n represents an integer of 1 to 15.

The photocurable composition of the embodiment of the present invention can also include a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70% by mole or more in a case where the total amount of the acid group and the basic group is taken as 100% by mole, and more preferably a resin consisting substantially of only an acid group. The acid group contained in the acidic dispersant (acidic resin) is preferably a carboxyl group. The acid value of the acidic dispersant (acidic resin) is preferably 1 to 80 mgKOH/g, more preferably 7 to 60 mgKOH/g, and still more preferably 12 to 40 mgKOH/g. In addition, the basic dispersant (basic resin) represents a resin in which the amount of the basic group is larger than the amount of the acid group. The basic dispersant (basic resin) is preferably a resin in which the amount of the basic group occupies more than 50% by mole in a case where a total amount of the amount of the acid group and the amount of the basic group is taken as 100% by mole. The basic group contained in the basic dispersant is preferably an amino group.

It is also preferable that the resin used as the dispersant is a graft copolymer. Since the graft copolymer has an affinity for a solvent due to the graft chain, it is excellent in the dispersibility of a pigment and the dispersion stability after a lapse of time. With regard to the details of the graft copolymer, reference can be made to the description in paragraph Nos. 0025 to 0094 of JP2012-255128A, the contents of which are incorporated herein by reference. Further, specific examples of the graft copolymer include the following resins. The following resins are also resins each having an acid group (alkali-soluble resins). In addition, examples of the graft copolymer include the resins described in paragraph Nos. 0072 to 0094 of JP2012-255128A, the contents of which are incorporated herein by reference.

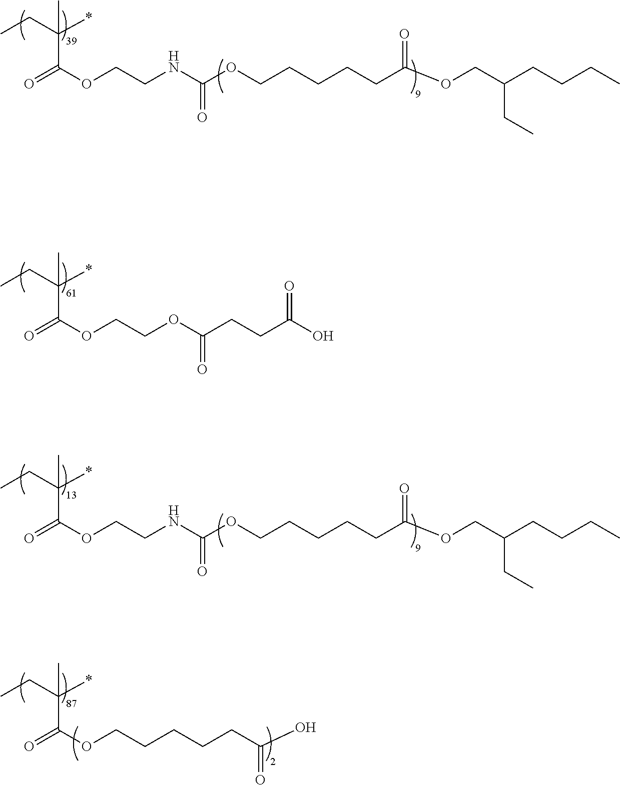

Moreover, in the present invention, it is also preferable to use an oligoimine-based copolymer including a nitrogen atom at at least one of the main chain or a side chain as the resin (dispersant). As the oligoimine-based copolymer, a resin having a main chain having a partial structure having a functional group with a pKa of 14 or less and side chains including a side chain having 40 to 10,000 atoms, and having a basic nitrogen atom in at least one of the main chain or the side chains is preferable. The basic nitrogen atom is not particularly limited as long as it is a nitrogen atom exhibiting basicity. With regard to the oligoimine-based copolymer, reference can be made to the description in paragraph Nos. 0102 to 0166 of JP2012-255128A, the contents of which are incorporated herein by reference. As the oligoimine-based copolymer, the resins described in paragraph Nos. 0168 to 0174 of JP2012-255128A can be used.

As the dispersant, a commercially available product thereof can also be used. For example, the products described in paragraph No. 0129 of JP2012-137564A can also be used as the dispersant. Examples thereof include DISPERBYK series manufactured by BYK Chemie (for example, DISPERBYK-161). In addition, the resin described as the dispersant can also be used in applications other than the dispersant. For example, the resin can also be used as a binder.

The content of the resin in the total solid content of the photocurable composition is preferably 10% to 40% by mass. The lower limit is preferably 15% by mass or more, and more preferably 20% by mass or more. The upper limit is preferably 35% by mass or less, more preferably 32% by mass or less, and still more preferably 30% by mass or less. In addition, the content of the resin having an acid group in the total solid content of the photocurable composition is preferably 5% to 3K % by mass. The lower limit is preferably 8% by mass or more, and more preferably 13% by mass or more. The upper limit is preferably 33% by mass or less, more preferably 28% by mass or less, and still more preferably 25% by mass or less.

Furthermore, it is preferable that the photocurable composition of the embodiment of the present invention includes a resin having a solubility parameter such that an absolute value of a difference between the solubility parameter and a solubility parameter of the organic solvent included in the above-mentioned developer is 3.5 MPa^{0.5} or less (preferably 3 MPa or less, more preferably 2.5 MPa^{0.5} or less, and still more preferably 2 MPa^{0.5} or less) (hereinafter also referred to as a resin A). According to this aspect, a more excellent pattern forming property is easily obtained. Furthermore, it is easy to more effectively suppress the generation of development residues. Moreover, it is more preferable that the resin A has a solubility parameter such that an absolute value of a difference from the solubility parameter and the solubility parameter of the organic solvent included in the above-mentioned rinsing liquid is 5.5 MPa^{0.5} or less (preferably 5 MPa^{0.5} or less, and more preferably 4 MPa^{0.5} or less). According to this aspect, it is possible to more effectively remove the development residues while suppressing the pattern to be swollen, and the like caused by the rinsing liquid during the rinsing step.

The content of the resin A having an acid group in the total solid content of the photocurable composition is preferably 3% to 36% by mass. The lower limit is preferably 4% by mass or more, and more preferably 6% by mass or more. The upper limit is preferably 33% by mass or less, more preferably 27% by mass or less, and still more preferably 24% by mass or less. In addition, the content of the resin A in the total amount of the resin is preferably 30% to 100% by mass, more preferably 50% to 100% by mass, and still more preferably 70% to 100% by mass.

Furthermore, the photocurable composition of the embodiment of the present invention preferably includes a resin having a CLogP value such that an absolute value of a difference between a CLogP value and the CLogP value of the organic solvent included in the above-mentioned developer is 2 or less (preferably 1.5 or less, and more preferably 1 or less) (hereinafter also referred to as a resin B). According to this aspect, a more excellent pattern forming property is easily obtained. Furthermore, it is easy to more effectively suppress the generation of development residues. Moreover, it is more preferable that the resin B has a CLogP value such that an absolute value of a difference between the CLogP value and the CLogP value of the organic solvent included in the above-mentioned rinsing liquid is 0.5 to 3 (preferably 1 to 2.5, and more preferably 1.5 to 2). According to this aspect, it is possible to more effectively remove the development residues while suppressing the pattern to be swollen, and the like caused by the rinsing liquid during the rinsing step. In addition, it is particularly preferable that the resin B further satisfies the requirements of the resin A as described above.

The content of the resin B having an acid group in the total solid content of the photocurable composition is preferably 1% to 37% by mass. The lower limit is preferably 2% by mass or more, and more preferably 3% by mass or more. The upper limit is preferably 34% by mass or less, more preferably 29% by mass or less, and still more preferably 23% by mass or less. In addition, the content of the resin B in the total amount of the resin is preferably 40% to 100% by mass, more preferably 60% to 100% mass, and still more preferably 80% to 100% by mass.

The acid value of the entire resin contained in the photocurable composition of the embodiment of the present invention is preferably 20 mgKOH/g or less, more preferably 15 mgKOH/g or less, and still more preferably 12 mgKOH/g or less, from the viewpoints of the dispersion stability and the pattern forming property of the color material. The lower limit is preferably 2 mgKOH/g or more, more preferably 3 mgKOH/g or more, and still more preferably 5 mgKOH/g or more, from the viewpoints of the dispersion stability and the pattern forming property of the color material. Further, the amine value of the entire resin contained in the photocurable composition is preferably 10 mgKOH/g or less, more preferably 7 mgKOH/g or less, and still more preferably 5 mgKOH/g or less. The lower limit is preferably 1 mgKOH/g or more, more preferably 2 mgKOH/g or more, and still more preferably 3 mgKOH/g or more.

<<Polymerizable Monomer>>

The photocurable composition of the embodiment of the present invention can contain a polymerizable monomer. The polymerizable monomer is preferably a compound which is polymerizable by the action of a radical. That is, the polymerizable monomer is preferably a radically polymerizable monomer. The polymerizable monomer is preferably a compound having one or more ethylenically unsaturated bond groups, more preferably a compound having two or more ethylenically unsaturated bond groups, and still more preferably a compound having three or more ethylenically unsaturated bond groups. The upper limit of the number of the ethylenically unsaturated bond groups is, for example, preferably 15 or less, and more preferably 6 or less. Examples of the ethylenically unsaturated bond group include a vinyl group, a styrene group, a (meth)allyl group, and a (meth)acryloyl group, with the (meth)acryloyl group being preferable. The polymerizable monomer is preferably a trifunctional to pentadecafunctional (meth)acrylate compound, and more preferably a trifunctional to hexafunctional (meth)acrylate compound.

The molecular weight of the polymerizable monomer is preferably less than 2,000. The upper limit is preferably 1,500 or less, and more preferably 1,000 or less. The lower limit is preferably 100 or more, more preferably 150 or more, and still more preferably 250 or more.

The solubility parameter of the polymerizable monomer is preferably 18 to 24 MPa^{0.5}. The lower limit is preferably 19 MPa^{0.5} or more, and more preferably 20 MPa^{0.5} or more. The upper limit is preferably 23 MPa^{0.5} or less, and more preferably 22 MPa^{0.5} or less. In a case where the solubility parameter of the polymerizable monomer is within the range, a more excellent pattern forming property can be easily obtained. Furthermore, it is easy to more effectively suppress the generation of development residues.

The polymerizable group value of the polymerizable monomer is preferably 1 mmol/g or more, more preferably 6 mmol/g or more, and still more preferably 10 mmol/g or more. The upper limit is preferably 30 mmol/g or less. Furthermore, the polymerizable group value of the polymerizable monomer was calculated by dividing the number of the polymerizable groups included in one molecule of the polymerizable monomer by the molecular weight of the polymerizable monomer. Further, the ethylenically unsaturated bond group value (hereinafter referred to as C═C value) of the polymerizable monomer is preferably 1 mmol/g or more, more preferably 6 mmol/g or more, and still more preferably 10 mmol/g or more from the viewpoint of curability. The upper limit is preferably 30 mmol/g or less. The C═C value of the polymerizable monomer was calculated by dividing the number of the ethylenically unsaturated bond groups included in one molecule of the polymerizable monomer by the molecular weight of the polymerizable monomer.

As the polymerizable monomer, ethyleneoxy-modified pentaerythritol tetraacrylate (as a commercially available product, NK ESTER ATM-35E manufactured by Shin-Nakamura Chemical Co., Ltd.); dipentaerythritol triacrylate (as a commercially available product, KAYARAD D-330 manufactured by Nippon Kayaku Co., Ltd.); dipentaerythritol tetraacrylate (as a commercially available product, KAYARAD D-320 manufactured by Nippon Kayaku Co., Ltd.); dipentaerythritol penta(meth)acrylate (as a commercially available product, KAYARAD D-310 manufactured by Nippon Kayaku Co., Ltd.); dipentaerythritol hexa(meth)acrylate (as a commercially available product, KAYARAD DPHA manufactured by Nippon Kayaku Co., Ltd., A-DPH-12E, manufactured by Shin-Nakamura Chemical Co., Ltd.); and a compound having a structure in which the (meth)acryloyl group is bonded through an ethylene glycol residue and/or a propylene glycol residue are preferable. Further, examples of the polymerizable monomer include the polymerizable monomers described in paragraph Nos. 0034 to 0038 of JP2013-253224A and paragraph No. 0477 of JP2012-208494A, the contents of which are incorporated herein by reference. In addition, as the polymerizable monomer, diglycerin EO (ethylene oxide)-modified (meth) acrylate (M-460 as a commercial product; manufactured by Toagosei Co., Ltd.), pentaerythritol tetraacrylate (A-TMMT, manufactured by Shin-Nakamura Chemical Co., Ltd.), 1,6-hexanediol diacrylate (KAYARAD HDDA, manufactured by Nippon Kayaku Co., Ltd.), RP-1040 (manufactured by Nippon Kayaku Co., Ltd.), ARONIX TO-2349 (manufactured by Toagosei Co., Ltd.), NK OLIGO UA-7200 (manufactured by Shin-Nakamura Chemical Co., Ltd.), 8UH-1006 or 8UH-1012 (manufactured by Taisei Fine Chemical Co, Ltd.), or the like can also be used.

The polymerizable monomer used in the present invention is preferably a compound having neither an acid group nor a hydroxyl group for a reason that the hydrophobicity of the film is increased and the developability is more easily improved.

A compound having a caprolactone structure can also be used as the polymerizable monomer. With regard to examples of the compound having a caprolactone structure, reference can be made to the description in paragraphs 0042 to 0045 of JP2013-253224A, the contents of which are incorporated herein by reference. Examples of the compound having a caprolactone structure include DPCA-20, DPCA-30, DPCA-60, and DPCA-120, which are commercially available as KAYARAD DPCA series from Nippon Kayaku Co., Ltd.

A compound having an ethylenically unsaturated bond group and an alkyleneoxy group can also be used as the polymerizable monomer. As the compound having an ethylenically unsaturated bond group and an alkyleneoxy group, a compound having an ethylenically unsaturated bond group and an ethyleneoxy group and/or a propyleneoxy group is preferable, a compound having an ethylenically unsaturated bond group and an ethyleneoxy group is more preferable, and trifunctional to hexafunctional (meth)acylate compounds having 4 to 20 ethyleneoxy groups are still more preferable. Examples of a commercial product of the compound having an ethylenically unsaturated bond group and an alkyleneoxy group include SR-494 manufactured by Sartomer, which is a tetrafunctional (meth)acrylate having four ethyleneoxy groups, and KAYARAD TPA-330 which is a trifunctional (meth)acrylate having three isobutyleneoxy groups.

As the polymerizable monomer, a polymerizable monomer having a fluorene skeleton is preferably used. Examples of a commercially available product of the polymerizable monomer having a fluorene skeleton include OGSOL EA-0200 and EA-0300 (manufactured by Osaka Gas Chemicals Co., Ltd., a (meth)acrylate monomer having a fluorene skeleton).

As the polymerizable monomer, the urethane acrylates described in JP1973-041708B (JP-S48-041708B), JP1976-037193A (JP-S51-037193A), JP1990-032293B (JP-H02-032293B), or JP1990016765B (JP-H02-016765B), and the urethane compounds having an ethylene oxide skeleton described in JP1983-0498608 (JP-S8-049860B), JP1981-017654B (JP-S56-017654B), JP1987-039417B (JP-S62-039417B), or JP1987-039418B (JP-S62-039418B) is also suitable. Further, the addition-polymerizable compounds having an amino structure or a sulfide structure in the molecule described in JP1988-277653A (JP-S63-277653A), JP1988-260909A (JP-S63-260909A), or JP1989-105238A (JP-H01-105238A) can be used. Examples of a commercially available product thereof include UA-7200 (manufactured by Shin-Nakamura Chemical Co., Ltd.), DPHA-40H (manufactured by Nippon Kayaku Co., Ltd.), and UA-306H, UA-306T, UA-3061, AH-600, T-600 and AI-600 (manufactured by Kyoeisha Chemical Co., Ltd.).

Moreover, the compound described in JP2017-048367A, JP6057891B, or JP6031807B can also be used as the polymerizable monomer.

In addition, as the polymerizable monomer, 8UH-1006 or 8UH-1012 (manufactured by Taisei Fine Chemical Co., Ltd.), Light Acrylate POB-A0 (manufactured by Kyoeisha Chemical Co., Ltd.), or the like is also preferably used.

In a case where the photocurable composition of the embodiment of the present invention contains a polymerizable monomer, the content of the polymerizable monomer in the total solid content of the photocurable composition of the embodiment of the present invention is preferably 0.1% to 30% by mass. The lower limit is preferably 0.5% by mass or more, and more preferably 1% by mass or more. The upper limit is preferably 25% by mass or less, and more preferably 20% by mass or less.

Furthermore, the total content of the polymerizable monomer and the resin in the total solid content of the photocurable composition is preferably 17% to 57% by mass. The lower limit is preferably 22% by mass or more, more preferably 27% by mass or more, and still more preferably 32% by mass or more. The upper limit is preferably 52% by mass or less, more preferably 47% by mass or less, and still more preferably 42% by mass or less. Further, it is preferable that the polymerizable monomer is contained in an amount of 10 to 100 parts by mass with respect to 100 parts by mass of the resin. The lower limit is preferably 30 parts by mass or more, and more preferably 50 parts by mass or more. The upper limit is preferably 80 parts by mass or less, and more preferably 70 pans by mass or less.

In the photocurable composition of the embodiment of the present invention, the polymerizable monomer may be used alone or in combination of two or more kinds thereof.

In a case where two or more kinds of the polymerizable monomers are used, the total amount thereof is preferably within the range.

<<Photopolymerization Initiator>>

The photocurable composition of the embodiment of the present invention preferably includes a photopolymerization initiator. The photopolymerization initiator is not particularly limited and can be appropriately selected from known photopolymerization initiators. For example, a compound having photosensitivity to light ranging from the ultraviolet region to the visible region is preferable. The photopolymerization initiator is preferably a photoradical polymerization initiator.

Examples of the photopolymerization initiator include halogenated hydrocarbon derivatives (for example, a compound having a triazine skeleton and a compound having an oxadiazole skeleton), an acylphosphine compound, hexaaryl biimidazole, an oxime compound, an organic peroxide, a thio compound, a ketone compound, an aromatic onium salt, an α-hydroxyketone compound, and an α-aminoketone compound. From the viewpoint of the exposure sensitivity, as the photopolymerization initiator, a trihalomethyl triazine compound, a benzyl dimethyl ketal compound, the α-hydroxyketone compound, the α-aminoketone compound, the acylphosphine compound, a phosphine oxide compound, a metallocene compound, the oxime compound, a triarylimidazole dimer, an onium compound, a benzothiazole compound, a benzophenone compound, an acetophenone compound, a cyclopentadiene-benzene-iron complex, a halomethyl oxadiazole compound, and a 3-aryl-substituted coumarin compound are preferable, a compound selected from the oxime compound, the α-hydroxyketone compound, the α-aminoketone compound, and the acylphosphine compound is more preferable, and the oxime compound is still more preferable. With regard to the photopolymerization initiator, reference can be made to the description in paragraphs 0065 to 0111 of JP2014-130173A, the contents of which are incorporated herein by reference.

Examples of a commercially available product of the α-hydroxyketone compound include IRGACURE-184, DAROCUR-1173, IRGACURE-500, IRGACURE-2959, and IRGACURE-127 (all manufactured by BASF). Examples of a commercially available product of the α-aminoketone compound include IRGACURE-907, IRGACURE-369, IRGACURE-379, and IRGACURE-379EG (all manufactured by BASF). Examples of a commercially available product of the acylphosphine compound include IRGACURE-819 and DAROCUR-TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin 11 (1979, pp. 156-162), the compounds described in Journal of Photopolymer Science and Technology (1995, pp. 202-232), the compounds described in JP2000-066385A, the compounds described in JP2004-534797A, the compounds described in JP2017-019766A, the compounds described in JP6065596B, the compounds described in WO2015/152153A, and the compounds described in WO2017/051680A. Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one. Examples of a commercially available product thereof include IRGACURE-OXE01, IRGACURE-OXE02, IRGACURE-OXE03, and IRGACURE-OXE04 (all manufactured by BASF), TR-PBG-304 (manufactured by Changzhou Tronly New Electronic Materials Co., Ltd.), and ADEKA OPTOMER N-1919 (manufactured by ADEKA Corporation, a photopolymerization initiator 2 described in JP2012-014052A). In addition, as the oxime compound, a compound having no coloring property or a compound having high transparency and resistance to discoloration is preferably used. Examples of a commercially available product thereof include ADEKA ARKLS NCI-730, NCI-831, and NCI-930 (manufactured by ADEKA Corporation).

In the present invention, an oxime compound having a fluorene ring can also be used as the photopolymerization initiator. Specific examples of the oxime compound having a fluorene ring include the compounds described in JP2014-137466A. The contents thereof are incorporated herein by reference.

In the present invention, an oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compounds (C-3) described in JP2013-164471A. The contents thereof are incorporated herein by reference.

In the present invention, an oxime compound having a nitro group can also be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

In the present invention, an oxime compound having a benzofuran skeleton can be used as the photopolymerization initiator. Specific examples thereof include OE-01 to OE-75 described in WO2015/036910A.

Specific examples of the oxime compound which is preferably used in the present invention are shown below, but the present invention is not limited thereto.

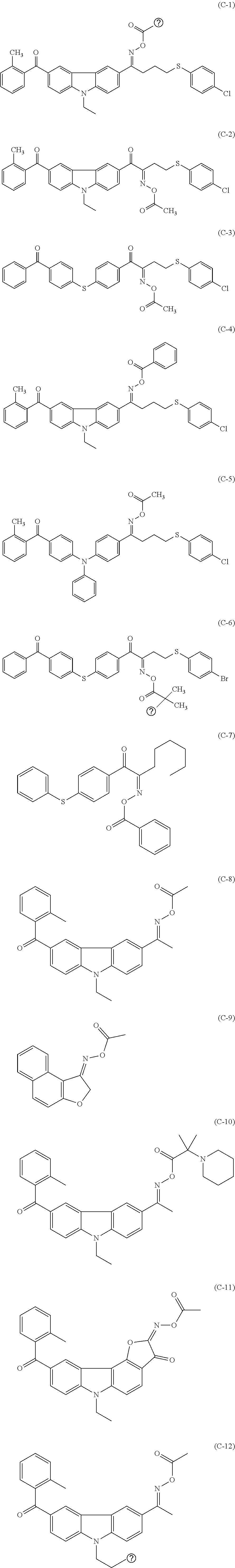

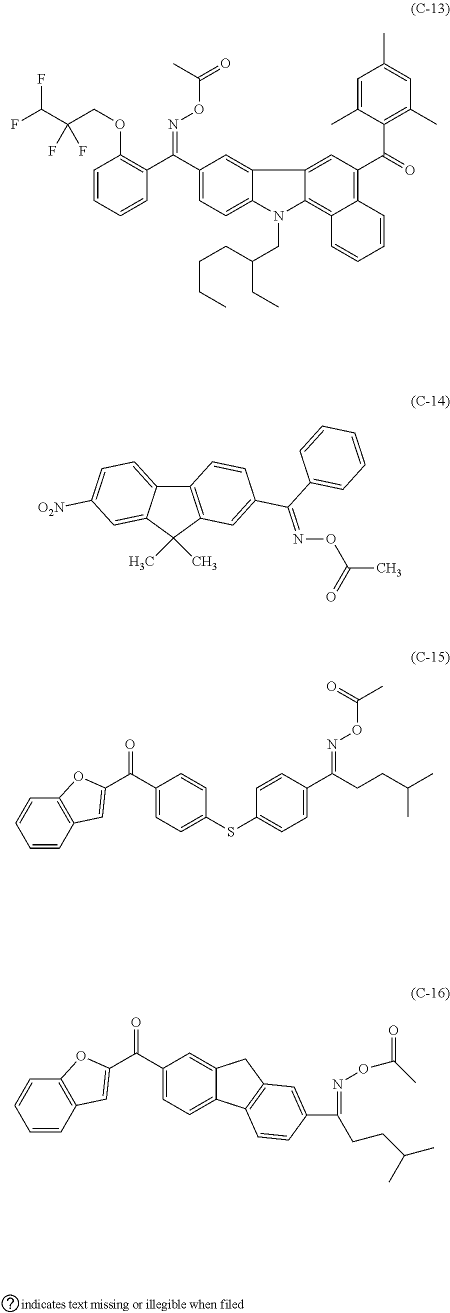 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\c1ccccc1)c1ccc2c(c1)C(C)(C)c1cc([N+](=O)[O-])ccc1-2 ; CC(=O)O/N=C(\CCC(C)C)c1ccc(Sc2ccc(C(=O)c3cc4ccccc4o3)cc2)cc1 ; CC(=O)O/N=C(\CCC(C)C)c1ccc2c(c1)Cc1cc(C(=O)c3cc4ccccc4o3)ccc1-2]

As the oxime compound, the compound having a maximum absorption wavelength in the wavelength range of 350 to 500 nm is preferable, the compound having a maximum absorption wavelength in the wavelength range of 360 to 480 nm is more preferable. Furthermore, the molar fight absorption coefficient at a wavelength of 365 nm or a wavelength of 405 nm of the oxime compound is preferably high from the viewpoint of the sensitivity, and is more preferably 1,000 to 300,000, still more preferably 2,000 to 300,000, and particularly preferably 5,000 to 200,000. The molar light absorption coefficient of the compound can be measured using a known method. The molar light absorption coefficient of the compound is preferably measured by, for example, a spectrophotometer (Cary-5 spectrophotometer manufactured by Varian Medical Systems. Inc.) at a concentration of 0.01 g/L using an ethyl acetate solvent.

In the present invention, a bifunctional or trifunctional or higher functional photoradical polymerization initiator may be used as the photopolymerization initiator. By using such a photoradical polymerization initiator, two or more radicals are generated from one molecule of the photoradical polymerization initiator, and therefore, a good sensitivity can be obtained. Further, in a case where a compound having an asymmetric structure is used, the crystallinity is lowered to improve the solubility in a solvent or the like, whereby precipitation over time hardly occurs, and therefore, the temporal stability of the composition can be improved. Specific examples of the bifunctional or trifunctional or higher functional photoradical polymerization initiator include the dimers of the oxime compounds described in JP2010-527339A, JP2011-524436A, WO2015/04565A, paragraph Nos. 0417 to 0412 of JP2016-532675A, paragraph Nos. 0039 to 0055 of WO2017/033680A, the compound (E) and the compound (G) described in JP2013-522445A, Cmpd I to 7 described in WO2016/034963A, the photoinitiators of oxime esters described in paragraph No. 0007 of JP2017-523465A, the photoinitiators described in paragraph Nos. 0020 to 0033 of JP2017-167399A, and the photopolymerization initiators (A) described in paragraph Nos. 0017 to 0026 of JP2017-151342A.

In a case where the photocurable composition of the embodiment of the present invention contains a photopolymerization initiator, the content of the photopolymerization initiator in the total solid content of the photocurable composition of the embodiment of the present invention is preferably 0.1% to 30% by mass. The lower limit is preferably 0.5% by mass or more, and more preferably 1% by mass or more. The upper limit is preferably 20% by mass or less, and more preferably 15% by mass or less. In the photocurable composition of the embodiment of the present invention, the photopolymerization initiator may be used alone or in combination of two or more kinds thereof. In a case where two or more kinds of the photopolymerization initiators are used, the total amount thereof is preferably within the range.

Further, the total content of the polymerizable monomer and the photopolymerization initiator in the total solid content of the photocurable composition is preferably 3% to 25% by mass. The lower limit is preferably 5% by mass or more, more preferably 7% by mass or more, and still more preferably 9% by mass or more. The upper limit is preferably 20% by mass or less, more preferably 18% by mass or less, and still more preferably 16% by mass or less. Further it is preferable that 25 to 300 parts by mass of the photopolymerization initiator is contained with respect to 100 parts by mass of the polymerizable monomer. The lower limit is preferably 50 parts by mass or more, and more preferably 75 parts by mass or more. The upper limit is preferably 200 parts by mass or less, and more preferably 150 parts by mass or less.

<<Compound Having Cyclic Ether Group>>

The photocurable composition of the embodiment of the present invention can contain a compound having a cyclic ether group. Examples of the cyclic ether group include an epoxy group and an oxetanyl group. The compound having a cyclic ether group is preferably a compound having an epoxy group. Examples of the compound having an epoxy group include compounds having one or more epoxy groups in one molecule, and a compound having two or more epoxy groups is preferable. It is preferable that 1 to 100 epoxy groups are contained in one molecule. The upper limit of the number of the epoxy groups can be, for example, 10 or less, or can be 5 or less. The lower limit of the number of the epoxy groups is preferably 2 or more. As the compound having an epoxy group, the compounds described in paragraph Nos. 0034 to 0036 of JP2013-011869A, paragraph Nos. 0147 to 0156 of JP2014-043556A, and paragraph Nos. 0085 to 0092 of JP2014-089408A, or JP2017-179172A can also be used. The contents of the publications are incorporated herein by reference.

The compound having an epoxy group may be a low-molecular compound (having, for example, a molecular weight of less than 2,000, and further less than 1,000), or a high-molecular compound (macromolecule) (having, for example, a molecular weight of 1,000 or more, and in a case of a polymer, a weight-average molecular weight is 1,000 or more). The weight-average molecular weight of the compound having an epoxy group is preferably 200 to 100,000, more preferably 00 to 50,000. The upper limit of the weight-average molecular weight is preferably 10,000 or less, more preferably 5,000 or less, and still more preferably 3,000 or less.

An epoxy resin can be preferably used as the compound having an epoxy group. Examples of the epoxy resin include an epoxy resin which is a glycidyl etherified product of a phenol compound, an epoxy resin which is a glycidyl etherified product of various novolac resins, an alicyclic epoxy resin, an aliphatic epoxy resin, a heterocyclic epoxy resin, a glycidyl ester epoxy resin, a glycidyl amine-based epoxy resin, an epoxy resin which is a glycidylated product of halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3,300 g/eq, more preferably 310 to 1,700 g/eq, and still more preferably 310 to 1,000 g/eq.

Examples of a commercially available product of the compound having a cyclic ether group include EHPE3150 (manufactured by Daicel Chemical Industries, Ltd.), EPICLON N-695 (manufactured by DIC Corporation), MARPROOF G-0150M, G-0105SA, G-0130SP, G-0250SP, G-1005S, G-1005SA, G-1010S, G-2050M, G-01100, and G-01758 (all manufactured by NOF Corporation, epoxy group containing polymer).

In a case where the photocurable composition of the embodiment of the present invention contains a compound having a cyclic ether group, the content of the compound having a cyclic ether group in the total solid content of the photocurable composition is preferably 0.1% to 20% by mass. The lower limit is, for example, preferably 0.5% by mass or more, and more preferably 1% by mass or more. The upper limit is, for example, preferably 15% by mass or less, and more preferably 10% by mass or less. The compound having a cyclic ether group may be of only one kind or two or more kinds. In a case where two or more kinds of the compounds are used, the total amount thereof is preferably within the range.

<<Silane Coupling Agent>>

The photocurable composition of the embodiment of the present invention can contain a silane coupling agent. According to this aspect, it is possible to improve the adhesiveness of a film thus obtained to a support. In the present invention, the silane coupling agent means a silane compound having a hydrolyzable group and a functional group other than the hydrolyzable group. Further, the hydrolyzable group refers to a substituent which is directly connected to a silicon atom and is capable of forming a siloxane bond due to at least one of a hydrolysis reaction or a condensation reaction. Examples of the hydrolyzable group include a halogen atom, an alkoxy group, and an acyloxy group, and the alkoxy group is preferable. That is, it is preferable that the silane coupling agent is a compound having an alkoxysilyl group. Moreover, examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, with the amino group, the (meth)acryloyl group, or the epoxy group being preferable. Examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

The content of the silane coupling agent in the total solid content of the photocurable composition is preferably (0.1% to 5% by mass. The upper limit is preferably 3% by mass or less, and more preferably 2% by mass or less. The lower limit is preferably 0.5% by mass or more, and more preferably 1% by mass or more. The silane coupling agents may be of only one kind or of two or more kinds. In a case where two or more kinds of the silane coupling agents are used, the total amount thereof is preferably within the range.

<<Pigment Derivative>>

The photcurable composition of the embodiment of the present invention can contain a pigment derivative. In particular, in a case where a pigment is used as a color material, the photocurable composition of the embodiment of the present invention preferably further contains a pigment derivative. Examples of the pigment derivative include a compound having a structure in which a part of the pigment is substituted with an acid group, a basic group, a group having a salt structure, or a phthalimidomethyl group. As the pigment derivative, a compound represented by Formula (B1) is preferable.

PL-(X)ₙ)ₘ (B1)

In Formula (B1), P represents a coloring agent structure, L represents a single bond or a linking group, X represents an acid group, a basic group, a group having a salt structure, or a phthalimidomethyl group, m represents an integer of 1 or more, n represents an integer of 1 or more, in a case where m represents 2 or more, a plurality of L's and a plurality of X's may be the same as or different from each other, and in a case where n represents 2 or more, a plurality of X's may be the same as or different from each other.

As the coloring agent structure represented by P, at least one selected from a pyrrolopyrrole coloring agent structure, a diketopyrrolopyrrole coloring agent structure, a quinacridone coloring agent structure, an anthraquinone coloring agent structure, a dianthraquinone coloring agent structure, a benzoisoindole coloring agent structure, a thiazine indigo coloring agent structure, an azo coloring agent structure, a quinophthalone coloring agent structure, a phthalocyanine coloring agent structure, a naphthalocyanine coloring agent structure, a dioxazine coloring agent structure, a perylene coloring agent structure, a perinone coloring agent structure, a benzimidazolone coloring agent structure, a benzothiazole coloring agent structure, a benzimidazole coloring agent structure, or a benzoxazole coloring agent structure is preferable, and at least one selected from the pyrrolopyrrole coloring agent structure, the diketopyrrolopyrrole coloring agent structure, the quinacridone coloring agent structure, or the benzimidazolone coloring agent structure is more preferable.

Examples of the linking group represented by L include a hydrocarbon group, a heterocyclic group, —NR—, —SO₂—, —S—, —O—, —CO—, or a group formed by combination thereof. R represents a hydrogen atom, an alkyl group, or an aryl group.

Examples of the acid group represented by X include a carboxyl group, a sulfo group, a carboxylic acid amido group, a sulfonic acid amido group, and an imide acid group. The carboxylic acid amido group is preferably a group represented by —NHCOR^{X1}. The sulfonic acid amido group is preferably a group represented by —NHSO₂R^{X2}. The imide acid group is preferably a group represented by —SO₂NHSO₂R^{X3}, —CONHSO₂R^{X4}, —CONHCOR^{X5}, or —SO₂NHCOR^{X6}. R^{X1} to R^{X6} each independently represent a hydrocarbon group or a heterocyclic group. The hydrocarbon group and the heterocyclic group represented by each of R^{X1} to R^{X6} may further have a substituent. The substituent is preferably a halogen atom, and more preferably a fluorine atom. Examples of the basic group represented by X include an amino group. Examples of the salt structure represented by X include a salt of the above-mentioned acid group or basic group.

Examples of the pigment derivative include compounds having the following structures. In addition, the compounds described in JP1981-118462A (JP-S56-118462A), JP1988-264674A (JP-S63-264674A), JP1989-217077A (JP-H01-217077A), JP1991-009961A (JP-H03-00996IA), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 in WO2017/038252A, or the like can also be used, the contents of which are incorporated herein by reference.

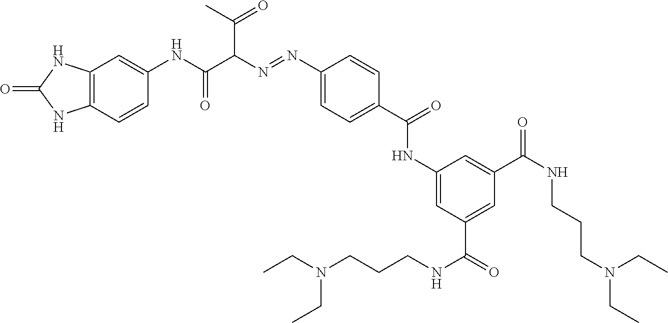 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

The content of the pigment derivative is preferably 1 to 50 parts by mass with respect to 100 parts by mass of the pigment. The lower limit value is preferably 3 parts by mass or more, and more preferably 5 parts by mass or more. The upper limit value is preferably 40 parts by mass or less, and more preferably 30 parts by mass or less. In a case where the content of the pigment derivative is within the range, the dispersibility of the pigment can be improved, and aggregation of the pigment can be efficiently suppressed. The pigment derivative may be used alone or in combination of two or more kinds thereof in combination. In a case where two or more kinds of the pigment derivatives are used, the total amount thereof is preferably within the range.

<<Solvent>>

The photocurable composition of the embodiment of the present invention can contain a solvent. Examples of the solvent include an organic solvent. Basically, the solvent is not particularly limited as long as it satisfies the solubility of the respective components or the coatability of the composition, Examples of the organic solvent include an ester-based solvent, a ketone-based solvent, an alcohol-based solvent, an amide-based solvent, an ether-based solvent, and a hydrocarbon-based solvent. With regard to the details of the organic solvent, reference can be made to the description in paragraph No. 0223 of WO2015/166779A, the contents of which are incorporated herein by reference. Further, an ester-based solvent substituted with a cyclic alkyl group or a ketone-based solvent substituted with a cyclic alkyl group can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-ethoxypropionate. 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. However, it is preferable in some cases to reduce aromatic hydrocarbons (benzene, toluene, xylene, ethylbenzene, and the like)(for example, the amount can be set to 50 parts per million (ppm) by mass or less, 10 ppm by mass or less, or i ppm by mass or less with respect to the total amount of the organic solvent) as a solvent for a reason in an environmental aspect or the like.

In the present invention, it is preferable to use a solvent having a small metal content, and the metal content of the solvent is, for example, preferably 10 parts per billion (ppb) by mass or less. A solvent at a level of parts per trillion (ppt) by mass may be used, as desired, and such a high-purity solvent is provided by, for example, Toyo Kasei Kogyo Co., Ltd. (The Chemical Daily, Nov. 13, 2015).

Examples of a method for removing impurities such as a metal from the solvent include distillation (for example, molecular distillation and thin-film distillation) and filtering using a filter. The pore diameter of a filter used for the filtering is preferably 10 μm or less, more preferably 5 m or less, and still more preferably 3 μm or less. As a material of the filter, polytetrafluoroethylene, polyethylene, or nylon is preferable.

The solvent may include an isomer (a compound having the same number of atoms and a different structure). Further, the solvent may include only one isomer or a plurality of isomers.

In the present invention, as the organic solvent, an organic solvent containing 0.8 mmol/L or less of a peroxide is preferable, and an organic solvent substantially not including a peroxide is more preferable.

The content of the solvent in the photocurable composition is preferably 10% to 95% by mass, more preferably 20% to 90% by mass, and still more preferably 30% to 90% by mass.

Moreover, it is preferable that the photocurable composition of the embodiment of the present invention does not substantially contain an environmentally regulated substance from the viewpoint of environmental regulation. In the present invention, an expression that the environmentally regulated substance is not substantially contained means that the content of the environmentally regulated substance in the photocurable composition is 50 ppm by mass or less, and the content is preferably 30 ppm by mass or less, more preferably 10 ppm by mass or less, and particularly preferably 1 ppm by mass or less. Examples of the environmentally regulated substance include benzenes; alkyl benzenes such as toluene and xylene; and halogenated benzenes such as chlorobenzene. These are registered as an environmentally regulated substance in accordance with a registration evaluation authorization and restriction of chemicals (REACH) rule, a pollutant release and transfer register (PRTR) method, a volatile organic compounds (VOC) regulation, or the like, and the amounts of the substance to be used and methods of handling the substance are strictly regulated. These compounds are used as a solvent in the production of the respective components used in the photocurable composition of the embodiment of the present invention in some cases, or are incorporated as a residual solvent into the photocurable composition in some cases. From the viewpoints of human safety and environmental consideration, it is preferable to reduce these substances as much as possible. Examples of a method for reducing the amount of the environmentally regulated substance include a method of heating or depressurizing the inside of a system to make it equal to or higher than the boiling point of the environmentally regulated substance to evaporate the environmentally regulated substance out of the system and reduce it. In addition, in a case where a small amount of an environmentally regulated substance is evaporated, it is also useful to make the corresponding solvent and a solvent having a boiling point equivalent to that of the corresponding solvent be azeotropic in order to enhance the efficiency. Furthermore, in a case where a compound having radical polymerizability is contained, a polymerization inhibitor or the like may be added to perform evaporation under reduced pressure, in order to suppress the crosslinking between molecules due to a progress of a radical polymerization reaction during the evaporation under reduced pressure. These evaporation methods can be available in any step out of a step with raw materials, a step with products obtained by reaction of the raw materials (for example, a resin solution after polymerization or a polyfunctional monomer solution), or a step with a composition produced by mixing these compounds.

<<Polymerization Inhibitor>>

The photocurable composition of the embodiment of the present invention can contain a polymerization inhibitor. Examples of the polymerization inhibitor include hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-t-butylphenol), and N-nitrosophenylhydroxylamine salt (for example, an ammonium salt and a cerium salt). Among these, p-methoxyphenol is preferable. The content of the polymerization inhibitor in the total solid content of the photocurable composition is preferably 0.001% to 5% by mass.

<<Surfactant>>

The photocurable composition of the embodiment of the present invention can contain a surfactant. As the surfactant, various surfactants such as a fluorine-based surfactant, a nonionic surfactant, a cationic surfactant, an anionic surfactant, and a silicon-based surfactant can be used. With regard to the surfactant, reference can be made to the description in paragraph Nos. 0239 to 0245 of WO2015/166779A, the contents of which are incorporated herein by reference.

In the present invention, the surfactant is preferably a fluorine-based surfactant. By incorporating a silicon-based surfactant into the photocurable composition, liquid characteristics (in particular, fluidity) can be further improved and liquid saving properties can be further improved. In addition, it is also possible to form a film having a small thickness unevenness.

The fluorine content in the fluorine-based surfactant is suitably 3% to 40% by mass, more preferably 5% to 30% by mass, and particularly preferably 7% to 25% by mass. The fluorine-based surfactant in which the fluorine content falls within this range is effective in terms of the evenness of the thickness of the coating film or the liquid saving properties, and the solubility in the composition is also good.

Examples of the fluorine-based surfactant include the surfactants described in paragraph Nos. 0060 to 0064 of JP2014-041318A (paragraph Nos. 0060 to 0064 of corresponding WO2014/017669A), and the surfactants described in paragraph Nos. 0117 to 0132 of JP2011-132503A, the contents of which are incorporated herein by reference. Examples of a commercially available product of the fluorine-based surfactant include MEGAFACE F171, F172, F173, F176, F177, F141, F142, F143, F144, R30, F437, F475, F479, F482, F554, and F780, EXP, and MFS-330 (all manufactured by DIC Corporation), FLUORAD FC430, FC431, and FC171 (all manufactured by Sumitomo 3M Ltd.), SURFLON S-382, SC-101, SC-103, SC-104, SC-105, SC-1068, SC-381, SC-383, and S-393, and KH-40 (all manufactured by Asahi Glass Co., Ltd.), and PolyFox PF636, PF656, PF6320, PF6520, and PF7002 (all manufactured by OMNOVA Solutions Inc.).

Moreover, as the fluorine-based surfactant, an acrylic compound having a molecular structure having a functional group containing a fluorine atom, in which the functional group containing a fluorine atom is cut by application of heat to volatilize the fluorine atom, can also be suitably used. Examples of the fluorine-based surfactant include MEGAFACE DS series manufactured by DIC Corporation (The Chemical Daily, Feb. 22, 2016) (Nikkei Business Daily, Feb. 23, 2016), for example, MEGAFACE DS-21, which can also be used.

Moreover, it is also preferable to use a polymer of a fluorine atom-containing vinyl ether compound having a fluorinated alkyl group or a fluorinated alkylene ether group and a hydrophilic vinyl ether compound as the fluorine-based surfactant. With regard to such a fluorine-based surfactant, reference can be made to the description in JP2016-216602A, the contents of which are incorporated herein by reference.

As the fluorine-based surfactant, a block polymer can also be used. Examples thereof include the compounds described in JP2011-089090A. As the fluorine-based surfactant, a fluorine-containing polymer compound can be preferably used, in which the fluorine-containing polymer compound includes a repeating unit derived from a (meth)acrylate compound having a fluorine atom; and a repeating unit derived from a (meth)acrylate compound having 2 or more (preferably 5 or more) alkyleneoxy groups (preferably an ethyleneoxy group and a propyleneoxy group). The following compound is also exemplified as the fluorine-based surfactant which is used in the present invention.

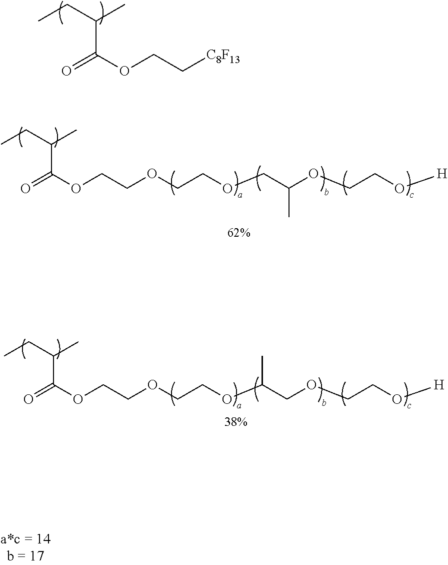

The weight-average molecular weight of the compounds is preferably 3,000 to 50,000, and is, for example 14,000. In the compounds, % representing a ratio of the repeating units is % by mole.

Moreover, a fluorine-containing polymer having an ethylenically unsaturated bond group in a side chain can also be used as the fluorine-based surfactant. Specific examples thereof include the compounds described in paragraph Nos. 0050 to X) and paragraph Nos. 0289 to 0295 of JP2010-164965A, for example, MEGAFACE RS-101, RS-102, RS-718K, and RS-72-K, manufactured by DTC Corporation. As the fluorine-based surfactant, the compounds described in paragraph Nos. 0015 to 0158 of JP2015-117327A can also be used.

Examples of the nonionic surfactant include glycerol, trimethylolpropane, trimethylolethane, and ethoxylate and propoxylate thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid esters, PLURONIC L10, L31, L61, L62, 10R5, 17R2 and 25R2 (manufactured by BASF), TETRONIC 304, 701, 704, 901, 904, and 150R1 (manufactured by BASF), SOLSEPERSE 20000 (manufactured by Lubrizol Japan Ltd.), NCW-101, NCW-1001, and NCW-1002 (manufactured by Wako Pure Chemical Industries, Ltd.), PIONIN D-6112, D-6112-W, and D-6315 (manufactured by Takemoto Oil & Fat Co., Ltd.), and OLFINE E1010, and SURFYNOL 104, 400, and 440 (manufactured by Nissin chemical industry Co., Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all manufactured by Dow Corning Toray Co., Ltd.), TSF-4440, TSF-4300, TSF-4445, TSF-4460, and TSF-4452 (all manufactured by Momentive Performance Materials Co., Ltd.), KP-341, KF-6001, and KF-6002 (all manufactured by Shin-Etsu Chemical Co., Ltd.), and BYK307, BYK323, and BYK330 (all manufactured by BYK Chemie). Further, as the silicon-based surfactant, a compound having the following structure can also be used.

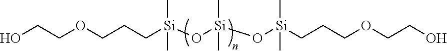

The content of the surfactant in the total solid content of the photocurable composition is preferably 0.001% by mass to 5.0% by mass, and more preferably 0.005% by mass to 3.0% by mass. The surfactant may be used alone or in combination of two or more kinds thereof. In a case where two or more kinds of the surfactants are used, the total amount thereof is preferably within the range.

<<Ultraviolet Absorber>>

The photocurable composition of the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. With reference to the details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Specific examples of the ultraviolet absorber include compounds having the following structures. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016).

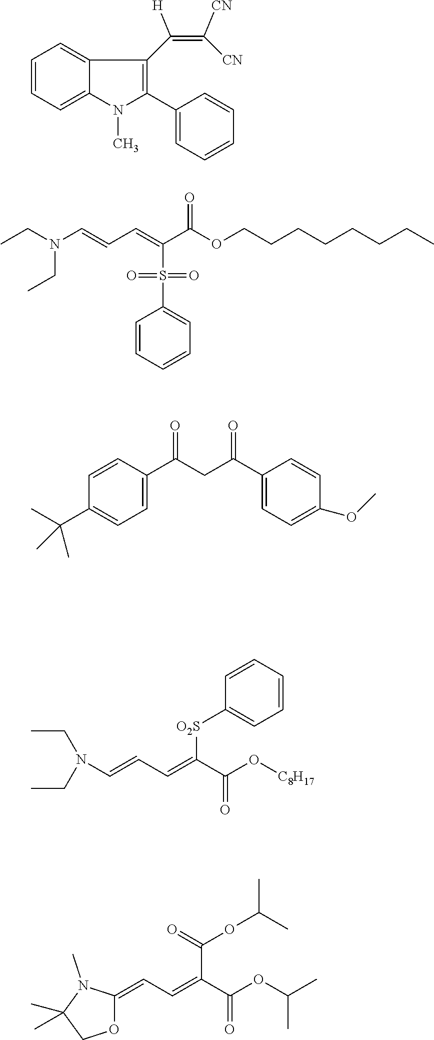

The content of the ultraviolet absorber in the total solid content of the photocurable composition is preferably 0.01% to 10% by mass, and more preferably 0.01% to 5% by mass. In the present invention, the ultraviolet absorber may be used alone or in combination of two or more kinds thereof. In a case where two or more kinds of the ultraviolet absorbers are used, the total amount thereof is preferably within the range.

<<Antioxidant>>

The photocurable composition of the embodiment of the present invention can contain an antioxidant. Examples of the antioxidant include a phenol compound, a phosphite compound, and a thioether compound.

As the phenol compound, any of phenol compounds which are known as a phenol antioxidant can be used. Preferred examples of the phenol compound include a hindered phenol compound. A compound having a substituent at a position (ortho-position) adjacent to a phenolic hydroxyl group is preferable. As the above-mentioned substituent, a substituted or unsubstituted alkyl group having 1 to 22 carbon atoms is preferable. Further, as the antioxidant, a compound having a phenol group and a phosphite group in the same molecule is also preferable. In addition, as the antioxidant, a phosphorus-based antioxidant can also be suitably used. Examples of the phosphorus-based antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl) phosphite. Examples of a commercially available product of the antioxidant include ADEKA STAB AO-20, ADEKA STAB AO-30, ADEKA STAB AO-40, ADEKA STAB AO-50, ADEKA STAB AO-50F, ADEKA STAB AO-60, ADEKA STAB AO-60G, ADEKA STAB AO-80, and ADEKA STAB AO-330 (all manufactured by ADEKA Corporation).

The content of the antioxidant in the total solid content of the photocurable composition is preferably 0.01% to 20% by mass, and more preferably 0.3% to 15% by mass. The antioxidant may be used alone or in combination of two or more kinds thereof. In a case where two or more kinds of the antioxidants are used, the total amount thereof is preferably within the range.

<<Other Components>>

The photocurable composition of the embodiment of the present invention may contain a sensitizer, a curing accelerator, a filler, a thermal curing accelerator, a plasticizer, and other auxiliary agents (for example, conductive particles, a filler, an antifoaming agent, a flame retardant, a leveling agent, a peeling accelerator, an aromatic chemical, a surface tension adjuster, or a chain transfer agent), as desired. By appropriately incorporating the components into the composition, properties such as film physical properties can be adjusted. With regard to the details of the components, reference can be made to, for example, paragraph No. 0183 or later of JP2012-003225A (corresponding to paragraph No. 0237 of US201310034812A), paragraph Nos. 0101 to 0104, and 0107 to 0109 of JP2008-250074A, and the like, the contents of which are incorporated herein by reference. Further, the photocurable composition of the embodiment of the present invention may contain a potential antioxidant, as desired. As the potential antioxidant, a compound with a site functioning as an antioxidant being protected with a protective group, in which the protective group leaves by heating the compound at 100° C. to 250° C. or by heating the compound at 80° C. to 200° C. in the presence of an acid/base catalyst, thus making the compound function as the antioxidant, may be mentioned. Examples of the potential antioxidant include the compounds described in WO2014/021023A, WO2017/030005A, and JP2017-008219A. Examples of a commercially available product thereof include ADEKA ARKLS GPA-5001 (manufactured by ADEKA Corporation).

For example, in a case where a film is formed by coating, the viscosity (23° C.) of the photocurable composition of the embodiment of the present invention is preferably in the range of 1 to 100 mPa·s. The lower limit is preferably 2 mPa·s or more, and more preferably 3 mPa·s or more. The upper limit is more preferably 50 mPa·s or less, still more preferably 30 mPa·s or less, and particularly preferably 15 mPa·s or less.

<Storage Container>

A storage container for each of the photocurable composition of the embodiment of the present invention is not particularly limited, and a known storage container can be used. Further, as the storage container, it is also preferable to use a multilayer bottle having an inner wall constituted with six layers from six kinds of resins or a bottle having a 7-layer structure from six kinds of resins for the purpose of suppressing incorporation of impurities into raw materials or compositions. Examples of such a container include the containers described in JP2015-123351A.

<Method for Preparing Photocurable Composition>

Each of the photocurable composition of the embodiment of the present invention can be prepared by mixing the above-mentioned components. In the preparation of the photocurable composition, all the components may be dissolved or dispersed at the same time in a solvent to prepare the photocurable composition, or two or more solutions or dispersion liquids in which the respective components are suitably formulated are prepared in advance, and mixed upon use (upon application) to prepare the photocurable composition, as desired.

Furthermore, in a case where the photocurable composition of the embodiment of the present invention includes particles such as a pigment, it is preferable to include a process for dispersing the particles. In the process for dispersing the particles, examples of a mechanical force that is used for dispersion of the particles include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. Further, in the pulverization of the particles in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the particles, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the particles, a refining treatment of particles in a salt milling process may be performed. With regard to the materials, the equipment, the treatment conditions, and the like used in the salt milling process, reference can be made to, for example, the description in JP2015-194521A and JP2012-046629A.

In the preparation of the photocurable composition of the embodiment of the present invention, it is preferable that the photocurable composition is filtered through a filter for the purpose of removing foreign matters, reducing defects, or the like. As the filter, any of filters that have been used in the related art for filtration use and the like may be used without particular limitation. Examples of the filter include filters formed of materials including, for example, a fluorine resin such as polytetrafluoroethylene (PTFE), a polyamide-based resin such as nylon (for example, nylon-6 and nylon-6,6), and a polyolefin resin (including a polyolefin resin having a high density and an ultrahigh molecular weight) such as polyethylene and polypropylene (PP). Among these materials, polypropylene (including a high-density polypropylene) and nylon are preferable. The pore diameter of the filter is suitably approximately 0.01 to 7.0 μm, preferably approximately 0.01 to 3.0 μm, and more preferably approximately 0.05 to 0.5 μm. In a case where the filter has a pore diameter in the range, it can remove fine foreign matters reliably. In addition, it is also preferable to use a fibrous filter material. In addition, examples of the fibrous filter material include a polypropylene fiber, a nylon fiber, and a glass fiber. Specific examples of the filter include filter cartridges of SBP type series (SBP008 and the like), TPR type series (TPR002, TPR005, and the like), or SHPX type series (SHPX003 and the like), manufactured by Roki Techno Co., Ltd. In a case of using a filter, different filters (for example, a first filter and a second filter) may be combined. Here, the filtration with each of the filters may be performed once or may be performed twice or more times. Furthermore, filters having different pore diameters within the above-mentioned range may be combined. In addition, the filtration through the first filter may be performed with only a dispersion liquid, the other components may be mixed therewith, and then the filtration through the second filter may be performed.

<Film>

Next, the film of an embodiment of the present invention will be described.

The film of the embodiment of the present invention is a film including a color material and a resin, in which an acid value of a solid content is 1 to 25 mgKOH/g and a contact angle with respect to pure water on the surface of the film after a lapse of 3,000 ms after dropwise addition of 8 μL of the pure water onto the film is 70° to 120°.

With regard to the film of the embodiment of the present invention, the upper limit of the contact angle is preferably 110° or less, more preferably 100° or less, and still more preferably 90° or less. Further, the lower limit of the contact angle is preferably 73° or more, more preferably 76° or more, and still more preferably 79° or more.

The film of the embodiment of the present invention is preferably a film obtained by using the above-mentioned photocurable composition of the embodiment of the present invention.

<Method for Producing Optical Filter>

Next, a method for manufacturing an optical filter of the embodiment of the present invention will be described. The method for manufacturing an optical filter of the embodiment of the present invention includes the method for producing a pattern of the embodiment of the present invention as described above.

Examples of the kinds of optical filters include a color filter and an infrared transmitting filter. Examples of the color filter include a filter having pixels (patterns) of hues selected from red, blue, green, cyan, magenta, and yellow. Furthermore, examples of the infrared transmitting filter include a filter which satisfies spectral characteristics with a maximum value of transmittances in the wavelength range of 400 to 64 nm of 20% or less (preferably 15% or less, and more preferably 10% or less) and a minimum value of transmittances in the wavelength range of 1,100 to 1,300 nm of 70% or more (preferably 75% or more, and more preferably 80% or more).

In a case of producing an optical filter having a plurality of kinds of pixels (patterns), at least one kind of pixels (patterns) may be formed using the above-described method for producing a pattern of the embodiment of the present invention, and all the pixels (patterns) may not be formed using the above-described method for producing a pattern of the embodiment of the present invention.

<Method for Producing Solid-State Imaging Element>

The method for producing the solid-state imaging element of an embodiment of the present invention includes the method for producing a pattern of the embodiment of the present invention as described above. The configuration of the solid-state imaging element is not particularly limited as long as the solid-state imaging element functions as a solid-state imaging element, but examples thereof include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light shielding film having openings only over the light receiving section of the photodiode, on the photodiodes and the transfer electrodes; have a device-protective film formed of silicon nitride or the like, which is formed to cover the entire surface of the light shielding film and the light receiving section of the photodiodes, on the light shielding film: and have a color filter on the device-protective film. In addition, the solid-state imaging element may also be configured, for example, to have a light collecting unit (for example, a microlens, which is the same hereinafter) on a device-protective film under a color filter (a side closer to the substrate), or to have a light collecting unit on a color filter. An imaging device comprising the solid-state imaging element of the embodiment of the present invention can also be used as an on-vehicle camera or a monitoring camera, in addition to a digital camera or electronic equipment (mobile phones or the like) having an imaging function.

<Method for Producing Image Display Device>

The method for manufacturing an image display device of an embodiment of the present invention includes the method for producing a pattern of the embodiment of the present invention as described above. Examples of the image display device include a liquid crystal display device and an organic electroluminescence display device. The definitions of image display devices or the details of the respective image display devices are described in, for example. “Electronic Display Device (Akio Sasaki. Kogyo Chosakai Publishing Co., Ltd., published in 1990)”, “Display Device (Sumiaki lbuki, Sangyo Tosho Co., Ltd., published in 1989)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention is applicable is not particularly limited, and can be applied to, for example, liquid crystal display devices employing various systems described in the “Liquid Crystal Display Technology for Next Generation”.

### EXAMPLES

Hereinbelow, the present invention will be described in more detail with reference to Examples. The materials, the amounts of materials used, the proportions, the treatment details, the treatment procedure, or the like shown in the Examples below may be modified if appropriate as long as the modifications do not depart from the spirit of the present invention. Therefore, the scope of the present invention is not limited to the specific Examples shown below.

<Measurement of Weight-Average Molecular Weight (Mw) of Resin>

The weight-average molecular weight of the resin was measured by means of gel permeation chromatography (GPC) under the following condition.

Types of columns: Columns formed by connection of TOSOH TSKgel Super HZM-H, TOSOH TSKgel Super HZ4000, and TOSOH TSKgel Super HZ2000, Developing solvent: Tetrhydrofuran, Column temperature: 40° C., Flow amount (amount of a sample to be injected): 1.0 μL (sample concentration: 0.1% by mass)

Device name: HLC-8220 manufactured by Tosoh Corporation, GPC Detector: Refractive index (R1) detector, Calibration curve base resin: Polystyrene resin

<Preparation of Photocurable Composition>

After mixing the raw materials described in the following table, the mixture was filtered though a nylon filter (manufactured by Nihon Pall Ltd.) having a pore diameter of 0.45 μm to prepare a photocurable composition having a concentration of solid contents of 20% by mass (compositions 1 to 43, R1, and R2). Further, the concentrations of solid contents of the photocurable compositions 1 to 22, 24 to 43, R1, and R2 were adjusted by changing the blending amount of propylene glycol monomethyl ether acetate (PGMEA). In addition, the concentration of solid contents of the photocurable composition for the composition 23 was adjusted by changing the blending amount of a mixed solvent of PGMEA and HI-MOL PM (polyethylene glycol monomethyl ether, molecular weight of 220, manufactured by Toho Chemical Industry Co., Ltd.)(PGMEA: HI-MOL PM-5:1 (mass ratio)).

TABLE 1

| | Pigment | | | | | | | | Polymerizable | | Polymerizable | |
|---|---|---|---|---|---|---|---|---|---|---|---|---|
| | dispersion liquid | | Dye | | Resin 1 | | Resin 2 | | monomer 1 | | monomer 2 | |
| | | Blending | | Blending | | Blending | | Blending | | Blending | | Blending |
| | | amount | | amount | | amount | | amount | | amount | | amount |
| | | (parts | | (parts | | (parts | | (parts | | (parts | | (parts |
| | Type | by mass) | Type | by mass) | Type | by mass) | Type | by mass) | Type | by mass) | Type | by mass) |
| Composition 1 | A1 | 500 | | | B1 | 3 | | | M1 | 8 | M2 | 8 |
| Composition 2 | A1 | 455 | | | B1 | 5 | | | M1 | 12 | M2 | 12 |
| Composition 3 | A1 | 530 | | | B1 | 3 | | | M1 | 5 | M2 | 5 |
| Composition 4 | A1 | 560 | | | B1 | 1 | | | M1 | 3 | M2 | 3 |
| Composition 5 | A1 | 590 | | | | | | | M1 | 1.5 | M2 | 1.5 |
| Composition 6 | A1 | 560 | | | B1 | 2 | | | M1 | 3 | M2 | 3 |
| Composition 7 | A1 | 560 | | | B1 | 3 | | | M1 | 3 | M2 | 3 |
| Composition 8 | A1 | 5 [symbol] 0 | | | B1 | 3 | | | M1 | 2 | M2 | 2 |
| Composition 9 | A1 | 560 | | | B1 | 5 | | | M1 | 1 | M2 | 1 |
| Composition 10 | A1 | 500 | | | B1 | 3 | | | M1 | 8 | M2 | 8 |
| Composition 11 | A1 | 500 | | | B1 | 3 | | | M1 | 8 | M2 | 8 |
| Composition 12 | A1 | 500 | | | B1 | 3 | | | M1 | 8 | M2 | 8 |
| Composition 13 | A1 | 500 | | | B1 | 3 | | | M1 | 8 | M2 | 8 |
| Composition 14 | A1 | 500 | | | B1 | 3 | | | M1 | 8 | M2 | 8 |
| Composition 15 | A1 | 500 | | | B1 | 3 | | | M3 | 8 | M2 | 8 |
| Composition 16 | A1 | 500 | | | B1 | 3 | | | M1 | 16 | | |
| Composition 17 | A1 | 500 | | | B1 | 3 | | | M2 | 16 | | |
| Composition 18 | A1 | 500 | | | B1 | 3 | | | M4 | 8 | M2 | 8 |
| Composition 19 | A1 | 500 | | | B1 | 3.5 | | | M1 | 8 | M2 | 8 |
| Composition 20 | A1 | 500 | | | B1 | [symbol] | | | M1 | 8 | M2 | 8 |
| Composition 21 | A1 | 500 | | | B2 | 3 | | | M1 | 8 | M2 | 8 |
| Composition 22 | A1 | 500 | | | B1 | 3 | | | M1 | 6 | M2 | 6 |
| Composition 23 | A2 | 500 | | | B1 | 3 | | | M1 | 8 | M2 | 8 |
| Composition 24 | A3 | 500 | | | B1 | 3 | | | M1 | 8 | M2 | 8 |
| Composition 25 | A4 | 500 | | | B1 | 3 | | | M1 | 8 | M2 | 8 |
| Composition 26 | A5 | 500 | | | B1 | 3 | | | M1 | 8 | M2 | 8 |
| Composition 27 | A6 | 500 | | | B1 | 3 | | | M1 | 8 | M2 | 8 |
| Composition 28 | A7 | 500 | | | B1 | 3 | | | M1 | 8 | M2 | 8 |
| Composition 29 | A1 | 500 | | | B1 | 2 | B2 | 1 | M1 | 8 | M2 | 8 |
| Composition 30 | A1 | 500 | | | B1 | 3 | | | M1 | 8 | M2 | 8 |
| Composition 31 | A8 | 300 | S1 | 15 | B1 | 3 | | | M1 | 8 | M2 | 8 |
| Composition 32 | A9 | 500 | | | B1 | 3 | | | M1 | 8 | M2 | 8 |
| Composition 33 | A9 | 700 | | | B1 | 3 | | | M1 | 8 | M2 | 8 |
| Composition 34 | A10 | 500 | | | B1 | 3 | | | M1 | 8 | M2 | 8 |
| Composition 35 | A10 | 1000 | | | B1 | 3 | | | M1 | 8 | M2 | 8 |
| Composition 36 | A12 | 500 | | | B1 | 3 | | | M1 | 8 | M2 | 8 |
| Composition 37 | A12 | 530 | | | B1 | 3 | | | M1 | 5 | M2 | 5 |
| Composition 38 | A12 | 560 | | | B1 | 1 | | | M1 | 3 | M2 | 3 |
| Composition 39 | A12 | 590 | | | | | | | M1 | 1.5 | M2 | 1.5 |
| Composition 40 | A1 | 500 | | | B3 | 3 | | | M1 | 8 | M2 | 8 |
| Composition 41 | A1 | 5 [symbol] 0 | | | B3 | 1 | | | M1 | 3 | M2 | 3 |
| Composition 42 | A1 | 500 | | | B4 | 3 | | | M1 | 8 | M2 | 8 |
| Composition 43 | A1 | 560 | | | B4 | 1 | | | M1 | 3 | M2 | 3 |
| Composition R1 | A11 | 500 | | | B1 | 3 | | | M1 | 8 | M2 | 8 |
| Composition R2 | A1 | 350 | | | B5 | 110 | | | M1 | 8 | M2 | 8 |
| | Initiator 1 | | Initiator 2 | | Surfactant | | Additive 1 | | Additive 2 | | Additive 3 | |
| | | Blending | | Blending | | Blending | | Blending | | Blending | | Blending |
| | | amount | | amount | | amount | | amount | | amount | | amount |
| | | (parts | | (parts | | (parts | | (parts | | (parts | | (parts |
| | Type | by mass) | Type | by mass) | Type | by mass) | Type | by mass) | Type | by mass) | Type | by mass) |
| Composition 1 | I1 | 5 | | | W1 | 0.1 | T1 | 2 | T2 | 0.5 | | |
| Composition 2 | I1 | [symbol] | | | W1 | 0.1 | T1 | 2 | T2 | 0.5 | | |
| Composition 3 | I1 | 4 | | | W1 | 0.1 | T1 | 2 | T2 | 0.5 | | |
| Composition 4 | I1 | 3 | | | W1 | 0.1 | T1 | 2 | T2 | 0.5 | | |
| Composition 5 | I1 | 1 | | | W1 | 0.1 | T1 | 2 | T2 | 0.5 | | |
| Composition 6 | I1 | 2 | | | W1 | 0.1 | T1 | 2 | T2 | 0.5 | | |
| Composition 7 | I1 | 1 | | | W1 | 0.1 | T1 | 2 | T2 | 0.5 | | |
| Composition 8 | I1 | 3 | | | W1 | 0.1 | T1 | 2 | T2 | 0.5 | | |
| Composition 9 | I1 | 3 | | | W1 | 0.1 | T1 | 2 | T2 | 0.5 | | |
| Composition 10 | I2 | 5 | | | W1 | 0.1 | T1 | 2 | T2 | 0.5 | | |
| Composition 11 | I3 | 5 | | | W1 | 0.1 | T1 | 2 | T2 | 0.5 | | |
| Composition 12 | I4 | 5 | | | W1 | 0.1 | T1 | 2 | T2 | 0.5 | | |
| Composition 13 | I5 | 5 | | | W1 | 0.1 | T1 | 2 | T2 | 0.5 | | |
| Composition 14 | I3 | 3 | I5 | 2 | W1 | 0.1 | T1 | 2 | T2 | 0.5 | | |
| Composition 15 | I1 | 5 | | | W1 | 0.1 | T1 | 2 | T2 | 0.5 | | |
| Composition 16 | I1 | 5 | | | W1 | 0.1 | T1 | 2 | T2 | 0.5 | | |
| Composition 17 | I1 | 5 | | | W1 | 0.1 | T1 | 2 | T2 | 0.5 | | |
| Composition 18 | I1 | 5 | | | W1 | 0.1 | T1 | 2 | T2 | 0.5 | | |
| Composition 19 | I1 | 5 | | | W1 | 0.1 | T1 | 2 | | | | |
| Composition 20 | I1 | 5 | | | W1 | 0.1 | | | T2 | 0.5 | | |
| Composition 21 | I1 | 3 | | | W1 | 0.1 | T1 | 2 | T2 | 0.5 | | |
| Composition 22 | I1 | 5 | | | W1 | 0.1 | T1 | 2 | T2 | 0.5 | T3 | 4 |
| Composition 23 | I1 | 5 | | | W1 | 0.1 | T1 | 2 | T2 | 0.5 | | |
| Composition 24 | I1 | 5 | | | W1 | 0.1 | T1 | 2 | T2 | 0.5 | | |
| Composition 25 | I1 | 5 | | | W1 | 0.1 | T1 | 2 | T2 | 0.5 | | |
| Composition 26 | I1 | 5 | | | W1 | 0.1 | T1 | 2 | T2 | 0.5 | | |
| Composition 27 | I1 | 5 | | | W1 | 0.1 | T1 | 2 | T2 | 0.5 | | |
| Composition 28 | I1 | 5 | | | W1 | 0.1 | T1 | 2 | T2 | 0.5 | | |
| Composition 29 | I1 | 5 | | | W1 | 0.1 | T1 | 2 | T2 | 0.5 | | |
| Composition 30 | I1 | 5 | | | W2 | 0.1 | T1 | 2 | T2 | 0.5 | | |
| Composition 31 | I1 | 5 | | | W2 | 0.1 | T1 | 2 | T2 | 0.5 | | |
| Composition 32 | I1 | 5 | | | W1 | 0.1 | T1 | 2 | T2 | 0.5 | | |
| Composition 33 | I1 | 5 | | | W1 | 0.1 | T1 | 2 | T2 | 0.5 | | |
| Composition 34 | I1 | 5 | | | W1 | 0.1 | T1 | 2 | T2 | 0.5 | | |
| Composition 35 | I1 | 5 | | | W1 | 0.1 | T1 | 2 | T2 | 0.5 | | |
| Composition 36 | I1 | 5 | | | W1 | 0.1 | T1 | 2 | T2 | 0.5 | | |
| Composition 37 | I1 | 4 | | | W1 | 0.1 | T1 | 2 | T2 | 0.5 | | |
| Composition 38 | I1 | 3 | | | W1 | 0.1 | T1 | 2 | T2 | 0.5 | | |
| Composition 39 | I1 | 1 | | | W1 | 0.1 | T1 | 2 | T2 | 0.5 | | |
| Composition 40 | I1 | 5 | | | W1 | 0.1 | T1 | 2 | T2 | 0.5 | | |
| Composition 41 | I1 | 3 | | | W1 | 0.1 | T1 | 2 | T2 | 0.5 | | |
| Composition 42 | I1 | 5 | | | W1 | 0.1 | T1 | 2 | T2 | 0.5 | | |
| Composition 43 | I1 | 3 | | | W1 | 0.1 | T1 | 2 | T2 | 0.5 | | |
| Composition R1 | I1 | 5 | | | W1 | 0.1 | T1 | 2 | T2 | 0.5 | | |
| Composition R2 | I1 | [symbol] | | | W1 | 0.1 | T1 | 2 | T2 | 0.5 | | |

[symbol]

indicates data missing or illegible when filed

The raw materials described in the table are as follows.

(Pigment Dispersion Liquid)

A1: Pigment dispersion liquid prepared by the following method

To a mixed liquid obtained by mixing 9 parts by mass of C. I. Pigment Green 58, 6 parts by mass of C. I. Pigment Yellow 185, 2.5 parts by mass of a pigment derivative Y1, 5 parts by mass of a dispersant D2, and 77.5 parts by mass of propylene glycol monomethyl ether acetate (PGMEA) was added 230 parts by mass of zirconia beads having a diameter of 0.3 mm, the mixture was subjected to a dispersion treatment for 3 hours using a paint shaker, and the beads were separated by filtration to prepare a pigment dispersion liquid A1. The pigment dispersion liquid A1 had a concentration of solid contents of 22.5% by mass and a pigment content of 15% by mass.

Pigment derivative Y1: a compound having the following structure.

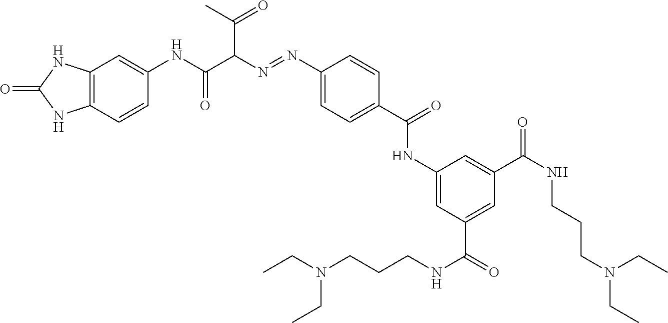 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

A2: Pigment dispersion liquid prepared by the following method

To a mixed liquid obtained by mixing 9 parts by mass of C. I. Pigment Green 36, 6 parts by mass of C. I. Pigment Yellow 150, 2.5 parts by mass of a pigment derivative Yl, 5 parts by mass of a dispersant D2, and 77.5 parts by mass of PGMEA was added 230 parts by mass of zirconia beads having a diameter of 0.3 mm, the mixture was subjected to a dispersion treatment for 3 hours using a paint shaker, and the beads were separated by filtration to prepare a pigment dispersion liquid A2. The pigment dispersion liquid A2 had a concentration of solid contents of 22.5% by mass and a pigment content of 15% by mass.

A3: Pigment dispersion liquid prepared by the following method

To a mixed liquid obtained by mixing 9 parts by mass of C. I. Pigment Green 58, 6 parts by mass of C. I. Pigment Yellow 139, 2.5 parts by mass of pigment derivative Y1, 5 parts by mass of a dispersant D2, and 77.5 parts by mass of PGMEA was added 230 parts by mass of zirconia beads having a diameter of 0.3 mm, the mixture was subjected to a dispersion treatment for 3 hours using a paint shaker, and the beads were separated by filtration to prepare a pigment dispersion liquid A3. The pigment dispersion liquid A3 had a concentration of solid contents of 22.5% by mass and a pigment content of 15% by mass.

A4: Pigment dispersion liquid prepared by the following method

To a mixed liquid obtained by mixing 10.5 parts by mass of C. I. Pigment Red 254, 4.5 parts by mass of C. I. Pigment Yellow 139, 2.0 parts by mass of a pigment derivative Y1, 5.5 parts by mass of a dispersant D2, and 77.5 parts by mass of PGMEA was added 230 parts by mass of zirconia beads having a diameter of 0.3 mm, the mixture was subjected to a dispersion treatment for 3 hours using a paint shaker, and the beads were separated by filtration to prepare a pigment dispersion liquid A4. This pigment dispersion liquid A4 had a concentration of solid contents of 22.5% by mass and a pigment content of 15% by mass.

A5: Pigment dispersion liquid prepared by the following method

To a mixed liquid obtained by mixing 10.5 parts by mass of C. I. Pigment Red 177, 4.5 parts by mass of C. I. Pigment Yellow 139, 2.0 parts by mass of a pigment derivative Y1, 5.5 parts by mass of a dispersant D2, and 77.5 parts by mass of PGMEA was added 230 parts by mass of zirconia beads having a diameter of 0.3 mm, the mixture was subjected to a dispersion treatment for 3 hours using a paint shaker, and the beads were separated by filtration to prepare a pigment dispersion liquid A5. The pigment dispersion liquid A5 had a concentration of solid contents of 22.5% by mass and a pigment content of 15% by mass.

A6: Pigment dispersion liquid prepared by the following method

To a mixed liquid obtained by mixing 12 parts by mass of C. I. Pigment Blue 15:6, 3 parts by mass of C. I. Pigment Violet 23, 2.7 parts by mass of a pigment derivative Y1, 4.8 parts by mass of a dispersant D2, and 77.5 parts by mass of PGMEA was added 230 parts by mass of zirconia beads having a diameter of 0.3 mm, the mixture was subjected to a dispersion treatment for 3 hours using a paint shaker, and the beads were separated by filtration to prepare a pigment dispersion liquid A6. This pigment dispersion liquid A6 had a concentration of solid contents of 22.5% by mass and a pigment content of 15% by mass.

A7: Pigment dispersion liquid prepared by the following method

To a mixed liquid obtained by mixing 12 parts by mass of C. I. Pigment Blue 15:6, 3 parts by mass of V dye 2 (acid value=7.4 mgKOH/g) described in paragraph No. 0292 of JP2015-041058A, 2.7 parts by mass of a pigment derivative Y, 4.8 parts by mass of a dispersant D2, and 77.5 parts by mass of PGMEA was added 230 parts by mass of zirconia beads having a diameter of 0.3 mm, the mixture was subjected to a dispersion treatment for 3 hours using a paint shaker, and the beads were separated by filtration to prepare a pigment dispersion liquid A7. This pigment dispersion liquid A7 had a concentration of solid contents of 22.5% by mass and a color material content (total amount of pigment and dye) of 15% by mass.

A8: Pigment dispersion liquid prepared by the following method

To a mixed liquid obtained by mixing 15 parts by mass of C. I. Pigment Blue 15:6, 2.7 parts by mass of a pigment derivative Y1, 4.8 parts by mass of a dispersant D2, and 77.5 parts by mass of PGMEA was added 230 pats by mass of zirconia beads having a diameter of 0.3 mm, the mixture was subjected to a dispersion treatment for 3 hours using a paint shaker, and the beads were separated by filtration to prepare a pigment dispersion liquid A8. This pigment dispersion liquid A8 had a concentration of solid contents of 22.5% by mass and a pigment content of 15% by mass.

A9: A pigment dispersion liquid A9 was prepared in the same manner as the pigment dispersion liquid A1, except that the same amount of a dispersant D3 was used instead of the dispersant D2 in the pigment dispersion liquid A1. This pigment dispersion liquid A9 had a concentration of solid contents of 22.5% by mass and a pigment content of 15% by mass.

A10: A pigment dispersion liquid A10 was prepared in the same manner as the pigment dispersion liquid A1, except that the same amount of a dispersant D4 was used instead of the dispersant D2 in the pigment dispersion liquid A1. The pigment dispersion liquid A10 had a concentration of solid contents of 225% by mass and a pigment content of 15% by mass.

A11: A pigment dispersion liquid A11 was prepared in the same manner as the pigment dispersion liquid A1, except that the same amount of a dispersant D5 was used instead of the dispersant D2 in the pigment dispersion liquid A1. The pigment dispersion liquid A11 had a concentration of solid contents of 22.5% by mass and a pigment content of 15% by mass.

A12: Pigment dispersion liquid prepared by the following method

To a mixed liquid obtained by mixing 10.13 parts by mass of C. I. Pigment Green 58, 6.75 parts by mass of C. I. Pigment Yellow 185, 2.81 parts by mass of a pigment derivative Y1, 2.81 parts by mass of a dispersant D1, and 77.5 parts by mass of PGMEA was added 230 parts by mass of zirconia beads having a diameter of 0.3 mm, the mixture was subjected to a dispersion treatment for 3 hours using a paint shaker, and the beads were separated by filtration to prepare a pigment dispersion liquid A12. This pigment dispersion liquid A12 had a concentration of solid contents of 22.5% by mass and a pigment content of 16.68% by mass.

(Dispersant)

Dispersant D1: Resin having the following structure (The numerical value attached to the main chain is a molar ratio and the numerical value attached to the side chain is the number of repeating units. Mw=10,000, acid value=24.4 mgKOH/g, solubility parameter 20.9 MPa^{0.5}, CLogP value=11.3)

Dispersant D2: Resin having the following structure (The numerical value attached to the main chain is a molar ratio and the numerical value attached to the side chain is the number of repeating units. Mw=10,000, acid value=52.5 mgKOH/g, solubility parameter 21.1 MPa^{0.5}, CLogP value=7.6)

Dispersant D3: Resin having the following structure (The numerical value attached to the main chain is a molar ratio and the numerical value attached to the side chain is the number of repeating units. Mw=10,000, acid value=79.4 mgKOH/g, solubility parameter=21.0 MPa^{0.5}, CLogP value=6.2)

Dispersant D4; Resin having the following structure (The numerical value attached to the main chain is a molar ratio and the numerical value attached to the side chain is the number of repeating units. Mw=10,000, acid value=122.1 mgKOH/g, solubility parameter=22.4 MPa^{0.5}, CLogP value=10.0)

Dispersant D5: Resin having the following structure (The numerical value attached to the main chain is a molar ratio and the numerical value attached to the side chain is the number of repeating units. Mw=10,000, acid value=150.2 mgKOH/g, solubility parameter 22.3 MPa^{0.5}, CLogP value 11.1)

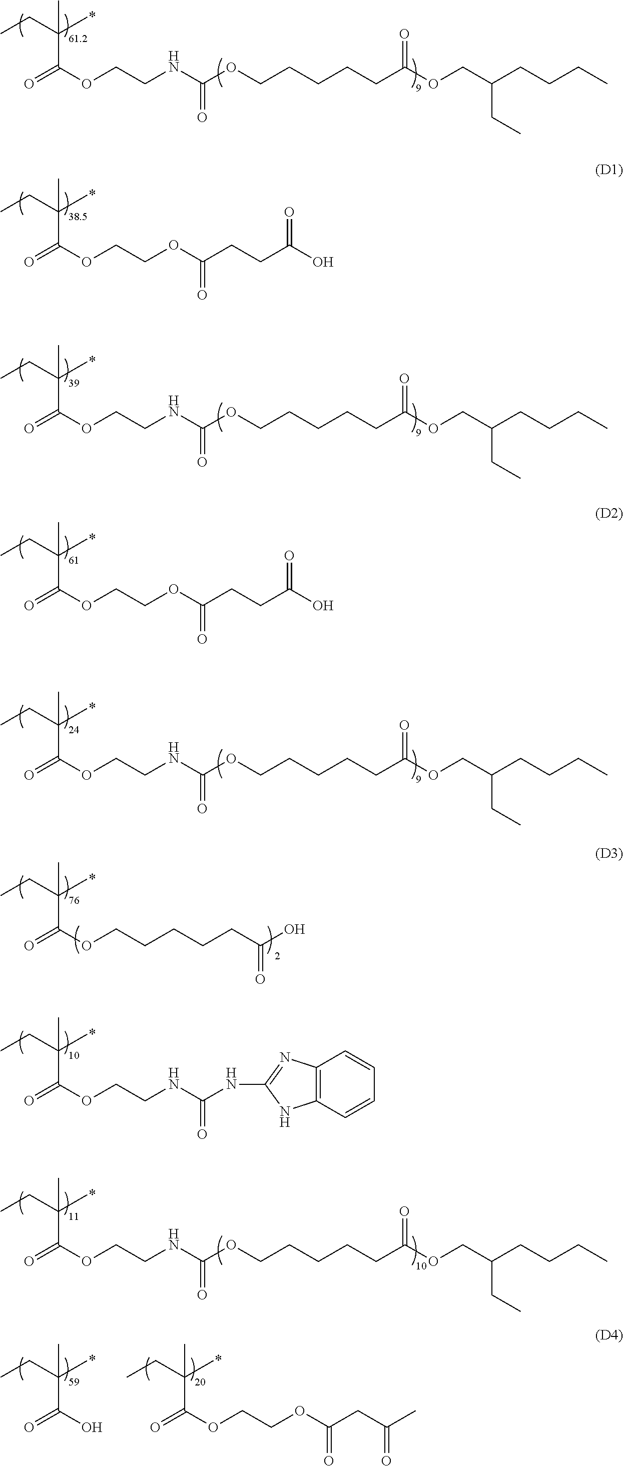

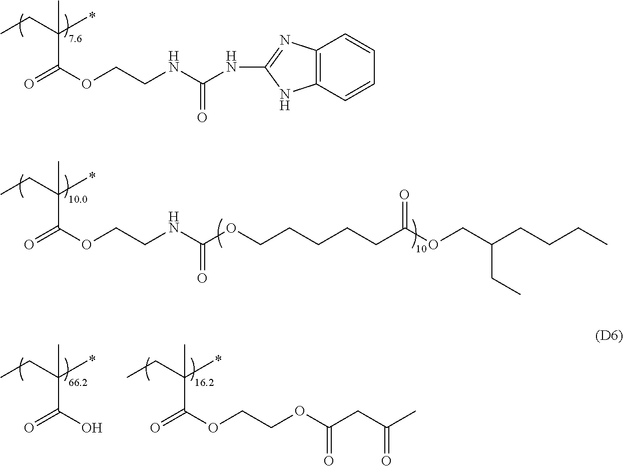

(Dye)

S1: Dye (A) described in paragraph No. 0444 of WO2017/038339A (acid value=56.66 mgKOH/g)

(Resin)

B1: Resin having the following structure (The numerical value attached to the main chain is a molar ratio. Mw=10,000, acid value=305 mgKOH/g, solubility parameter=21.2 MPa^{0.5}, CLogP value=2.1)

B2: Resin having the following structure (The numerical value attached to the main chain is a molar ratio. Mw=1,0000, acid value: 95 mgKOH/g, solubility parameter=19.6 MPa^{0.5}, CLogP value=1.6)

B3: Resin having the following structure (The numerical value attached to the main chain is a molar ratio. Mw=1,0000, acid value: 65.2 mgKOH/g, solubility parameter=23.4 MPa^{0.5}, CLogP value=1.0)

B4: Resin having the following structure (The numerical value attached to the main chain is a molar ratio. Mw=1,0000, acid value: 65.2 mgKOH/g, solubility parameter 21 MPa^{0.5}. CLogP value=2.7)

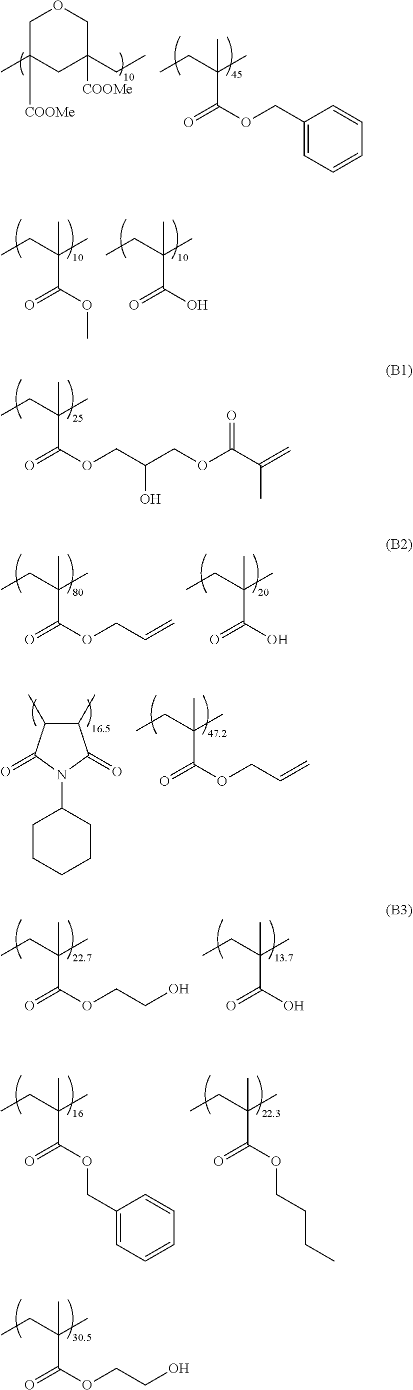

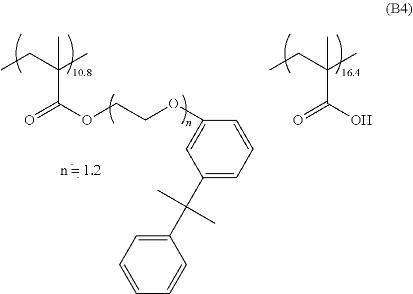

B5: DISPERBYK-161 (manufactured by BYK Chemie, acid value=0 mgKOH/g)

(Polymerizable Monomer)

M1: OGSOL EA-0300) (manufactured by Osaka Gas Chemical Co., Ltd., (meth)acrylate monomer having a fluorene skeleton, C═C value: 2.1 mmol/g)

M2: A compound having the following structure (C═C value: 10.4 mmol/g)

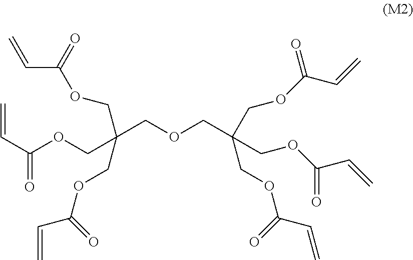 [SMILES: C=CC(=O)OCC(COCC(COC(=O)C=C)(COC(=O)C=C)COC(=O)C=C)(COC(=O)C=C)COC(=O)C=C]

M3: OGSOL EA-200 (manufactured by Osaka Gas Chemical Co., Ltd., (meth)acrylate monomer having a fluorene skeleton, C═C value: 3.55 mmol/g)

M4: A compound having the following structure (C═C value: 6.24 mmol/g)

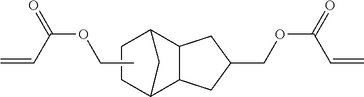

(Initiator)

I1 to I5: Compounds having the following structures

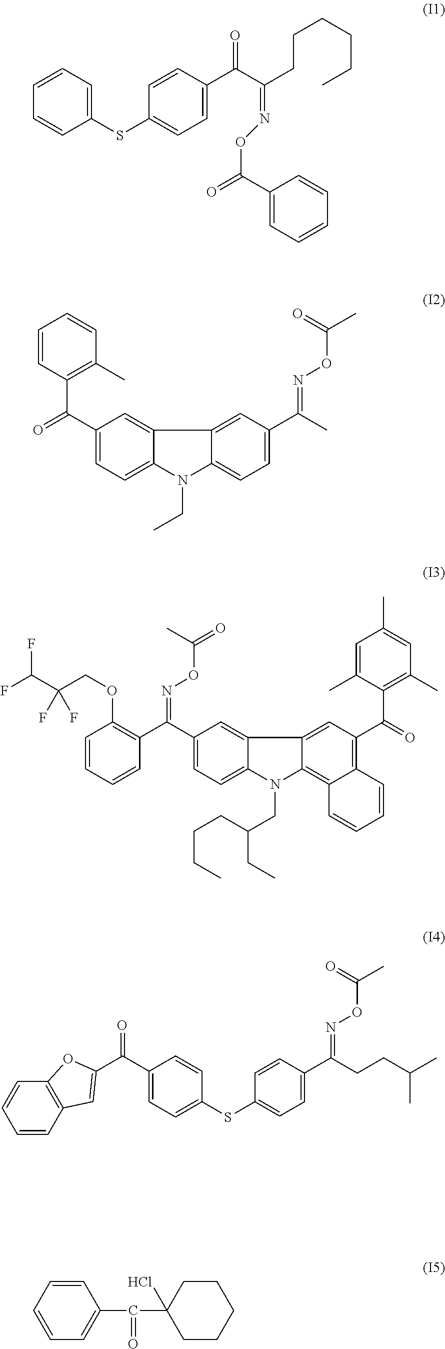 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\CCC(C)C)c1ccc(Sc2ccc(C(=O)c3cc4ccccc4o3)cc2)cc1 ; O=C(c1ccccc1)C1(Cl)CCCCC1]

(Surfactant)

W1: A compound having the following structure

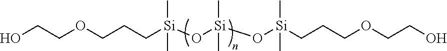

W2: A compound having the following structure (Mw=14,000, the numerical value of % indicating a ratio of repeating units is % by mole)

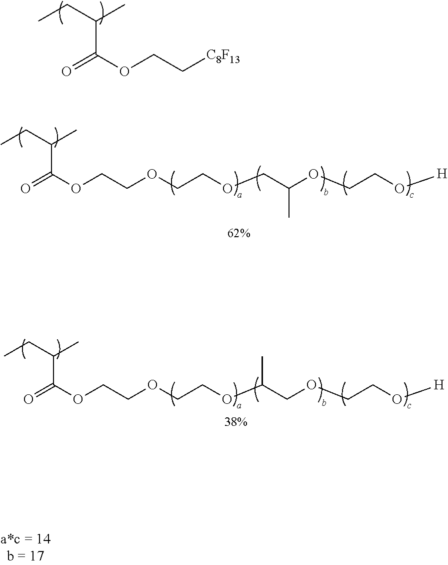

(Additive)

T1: EHPE3150 (manufactured by Daicel Corporation, epoxy resin)

T2: A compound having the following structure (silane coupling agent)

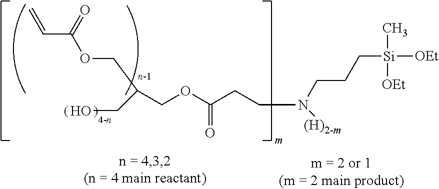

T3: A compound having the following structure (ultraviolet absorber)

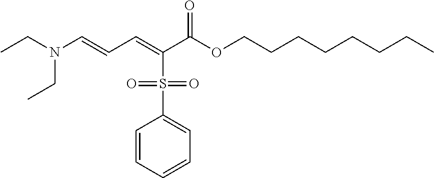 [SMILES: CCCCCCCCOC(=O)/C(=C/C=C/N(CC)CC)S(=O)(=O)c1ccccc1]

[Evaluation of Pattern Forming Property and Residue]

CT-4000L (manufactured by FUJIFILM Electronic Materials Co., Ltd.) was applied onto an 8-inch (20,32-cm) silicon wafer using a spin coater so that the thickness became 0.1 μm after post-baking, and heated at 220° C. for 300 seconds using a hot plate form an undercoat layer, thereby obtaining a silicon wafer (support) with an undercoat layer.

Next, each photocurable composition was applied by a spin coating method so that the film thickness after post-baking was a film thickness described in the following table. Then, the film was post-baked at 100° C. for 2 minutes using a hot plate. Subsequently, exposure was performed by irradiation with light through a mask having a Bayer pattern formed with a pixel (pattern) size of 1 μm square under the conditions shown in the following table.

Next, puddle development was performed for 60 seconds at 23° C. using a developer described in the table below.

Then, rinsing was performed with a spin shower, using the rinsing liquid shown in the following table.

Subsequently, pixels (patterns) were formed by heating the film at 200° C. for 5 minutes using a hot plate.

(Exposure Conditions)

Exposure 1: Exposure was performed with i-rays at an exposure dose of 200 mJ/cm² through a mask having a Bayer pattern with a pixel (pattern) size of 1 μm square formed therein, using an i-ray stepper exposure device FPA-3000i5+ (manufactured by Canon Inc.).

Exposure 2: Pulse exposure was performed with KrF rays at an exposure dose of 200 mJ/cm² through a mask having a Bayer pattern with a pixel (pattern) size of 1 μm square formed therein, using a KrF scanner exposure device (maximum instantaneous illuminance: 250,000,000 W/m² (average illuminance: 30,000 W/m²), pulse width: 30 nanoseconds, frequency: 4 kHz).

(Developer)

Developer 1: Cyclopentanone (solubility parameter 22.1 MPa^{0.5}, CLogP value=0.306, boiling point=130° C.)

Developer 2: Cyclohexanone (solubility parameter=20.3 MPa^{0.5}, CLogP value=0.865, boiling point=155° C.)

Developer 3: A mixed solution of cyclopentanone and cyclohexanone (cyclopentanone: 50% by mass, cyclohexanone: 50% by mass) (solubility parameter=21.2 MPa^{0.5}, CLogP value=0.5855, boiling point=142.5° C.)

(Rinsing Liquid)

Rinsing liquid 1: PGMEA (solubility parameter=17.8 MPa^{0.5}, CLogP value=0.60, boiling point=145° C.)

Rinsing liquid 2: water (solubility parameter=46.8 MPa^{0.5}, CLogP value=−1.32, boiling point=100° C.)

Rinsing liquid 3: EEP (solubility parameter=18.0 MPa^{0.5}, CLogP value=1.21, boiling point=126° C.)

(Evaluation Method for Pattern Forming Property)

With regard to the obtained pixels, an image area (pattern) was observed using a high-resolution field emission beam (FEB) length-measuring device (HITACHI CD-SEM) S9380II (manufactured by Hitachi High-Technologies Corporation).

A: A pattern having a target line width was formed without distortion, and a difference between the line width at the center of the pattern and the line width at the end was less than 5%.

B: A pattern having an almost aimed line width was formed, but a difference between the line width at the center of the pattern and the line width at the end was 5% or more and less than 10%.

C: A pattern having an almost aimed line width was formed, but a difference between the line width at the center of the pattern and the line width at the end was 10% or more and less than 30%.

D: Not corresponding to A to C, or a pattern could not be formed.

(Evaluation Method for Residue)

The obtained pixels were observed for residues in a non-image area (between the pixels) using a high-resolution field emission beam (FEB) length-measuring device (HITACHI CD-SEM) S9380II (manufactured by Hitachi High-Technologies Corporation).

A: No residue was seen at all.

B: Residues were in an area occupying more than 0% and less than 5% of the non-image area.

C: Residues were found in an area occupying 5% or more and less than 10% of the non-image area.

D: Residues were seen in an area occupying 10% or more of the non-image area.

(Evaluation of Minimum Adhesive Line Width)

In each of Test Examples, pixels (patterns) were formed by the same procedure as the procedure for forming the pixels (patterns) performed for evaluation of the pattern forming property and the residue, except that a mask having a Bayer pattern in which the pixel patterns were formed in 0.7 μm square, 0.8 μm square, 0.9 μm square, 1.0 μm square, 1.1 μm square, 1.2 μm square, 1.3 μm square, 1.4 μm square, 1.5 μm square, 1.7 μm square, 2.0 μm square, 3.0 μm square, 5.0 μm square, or 10.0 μm square was used. The patterns in 0.7 μm square, 0.8 μm square, 0.9 μm square. 1.0 μm square, 1.1 μm square, 1.2 μm square, 1.3 μm square, 1.4 μm square, 1.5 μm square, 1.7 μm square, 2.0 μm square, 3.0 μm square, 5.0 μm square, or 10.0 μm square were observed using a high-resolution FEB length-measuring device (HITACHI CD-SEM) S9380II (manufactured by Hitachi High-Technologies Corporation), and the minimum pattern size in which the patterns were formed without peeling was defined as a minimum adhesive line width.

(Measurement of Contact Angle)

Each of the photocurable compositions was applied onto a glass substrate by spin coating, and heated at 100° C. for 2 minutes to form a film having a film thickness shown in the following table. 8 μL of pure water was added dropwise to a film thus formed, and the contact angle of a film surface with respect to the pure water after a lapse of 3,000 ms was measured. In addition, the contact angle was measured using DM-701 manufactured by Kyowa Interface Science Co., Ltd.

TABLE 2

| | Photocurable composition | | | | | | | | | | |
|---|---|---|---|---|---|---|---|---|---|---|---|
| | mol | | | | | | | | | | |
| | | Color | | | | | | | | | |
| | | material | Film | Solid | | | | | | Minimum | |
| | | concen- | thick- | content | | | | Pattern | | adhesion | Contact |
| | | tration | ness | acid value | Exposure | | Rinsing | forming | | line widths | angle |
| | Type | (% by mass) | (μm) | [mgKOH/g] | condition | Developer | liquid | property | Residue | (μm) | (°) |
| Test | Composition 1 | 53. [symbol] 2 | 0. [symbol] | 10.1 | Exposure 1 | Developer 1 | Rinsing | A | A | 1.0 | 7 [symbol] |
| Example 1 | | | | | | | liquid 1 | | | | |
| Test | Composition 2 | 49.11 | 0. [symbol] | 9.7 | Exposure 1 | Developer 1 | Rinsing | A | A | 0.8 | 76 |
| Example 2 | | | | | | | liquid 1 | | | | |
| Test | Composition 3 | 57.26 | 0.47 | 10.7 | Exposure 1 | Developer 1 | Rinsing | B | A | 1.2 | 73 |
| Example 3 | | | | | | | liquid 1 | | | | |
| Test | Composition 4 | 60.61 | 0.44 | 10.8 | Exposure 1 | Developer 1 | Rinsing | B | B | 1.5 | 73 |
| Example 4 | | | | | | | liquid 1 | | | | |
| Test | Composition 5 | 63.51 | 0.42 | 11.1 | Exposure 1 | Developer 1 | Rinsing | C | C | 2.0 | 73 |
| Example 5 | | | | | | | liquid 1 | | | | |
| Test | Composition 6 | 60.61 | 0.44 | 11.0 | Exposure 1 | Developer 1 | Rinsing | C | B | 1.2 | 73 |
| Example 6 | | | | | | | liquid 1 | | | | |
| Test | Composition 7 | 60.61 | 0.44 | 11.3 | Exposure 1 | Developer 1 | Rinsing | C | A | 1.2 | 73 |
| Example 7 | | | | | | | liquid 1 | | | | |
| Test | Composition 8 | 60.61 | 0.44 | 11.3 | Exposure 1 | Developer 1 | Rinsing | C | A | 1.0 | 73 |
| Example 8 | | | | | | | liquid 1 | | | | |
| Test | Composition 9 | 60.61 | 0.44 | 11.7 | Exposure 1 | Developer 1 | Rinsing | C | A | 1.0 | 73 |
| Example 9 | | | | | | | liquid 1 | | | | |
| Test | Composition 10 | 53.92 | 0.50 | 10.1 | Exposure 1 | Developer 1 | Rinsing | A | A | 1.0 | 76 |
| Example 10 | | | | | | | liquid 1 | | | | |
| Test | Composition 11 | 53.92 | 0.50 | 10.1 | Exposure 1 | Developer 1 | Rinsing | A | A | 1.1 | 75 |
| Example 11 | | | | | | | liquid 1 | | | | |
| Test | Composition 12 | 53.92 | 0.50 | 10.1 | Exposure 1 | Developer 1 | Rinsing | A | A | 1.2 | 7 [symbol] |
| Example 12 | | | | | | | liquid 1 | | | | |
| Test | Composition 13 | 53.92 | 0.50 | 10.1 | Exposure 1 | Developer 1 | Rinsing | C | A | 1.0 | 7 [symbol] |
| Example 13 | | | | | | | liquid 1 | | | | |
| Test | Composition 14 | 53.92 | 0.50 | 10.1 | Exposure 1 | Developer 1 | Rinsing | A | A | 1.0 | 7 [symbol] |
| Example 14 | | | | | | | liquid 1 | | | | |
| Test | Composition 15 | 53.92 | 0.50 | 10.1 | Exposure 1 | Developer 1 | Rinsing | A | A | 1.2 | 7 [symbol] |
| Example 15 | | | | | | | liquid 1 | | | | |
| Test | Composition 16 | 53.92 | 0.50 | 10.1 | Exposure 1 | Developer 1 | Rinsing | A | A | 1.2 | 7 [symbol] |
| Example 16 | | | | | | | liquid 1 | | | | |
| Test | Composition 17 | 53.92 | 0.50 | 10.1 | Exposure 1 | Developer 1 | Rinsing | A | B | 1.5 | 7 [symbol] |
| Example 17 | | | | | | | liquid 1 | | | | |
| Test | Composition 18 | 53.92 | 0.50 | 10.1 | Exposure 1 | Developer 1 | Rinsing | A | A | 1.5 | 75 |
| Example 18 | | | | | | | liquid 1 | | | | |
| Test | Composition 19 | 53.92 | 0.50 | 10.2 | Exposure 1 | Developer 1 | Rinsing | A | A | 1.5 | 75 |
| Example 19 | | | | | | | liquid 1 | | | | |
| Test | Composition 20 | 53.92 | 0.50 | 10.5 | Exposure 1 | Developer 1 | Rinsing | B | A | 1.0 | 74 |
| Example 20 | | | | | | | liquid 1 | | | | |
| Test | Composition 21 | 54.70 | 0.49 | 10.2 | Exposure 1 | Developer 1 | Rinsing | A | A | 1.0 | 75 |
| Example 21 | | | | | | | liquid 1 | | | | |
| Test | Composition 22 | 53.92 | 0.50 | 10.1 | Exposure 1 | Developer 1 | Rinsing | A | B | 1.0 | 75 |
| Example 22 | | | | | | | liquid 1 | | | | |
| Test | Composition 23 | 53.92 | 0.50 | 10.1 | Exposure 1 | Developer 1 | Rinsing | A | A | 1.2 | 75 |
| Example 23 | | | | | | | liquid 1 | | | | |
| Test | Composition 24 | 53.92 | 0.50 | 10.1 | Exposure 1 | Developer 1 | Rinsing | A | A | 1.2 | 75 |
| Example 24 | | | | | | | liquid 1 | | | | |
| Test | Composition 26 | 53.92 | 0.50 | 10.1 | Exposure 1 | Developer 1 | Rinsing | A | A | 1.5 | 75 |
| Example 25 | | | | | | | liquid 1 | | | | |
| Test | Composition 26 | 53.92 | 0.50 | 10.1 | Exposure 1 | Developer 1 | Rinsing | A | A | 1.5 | 75 |
| Example 26 | | | | | | | liquid 1 | | | | |
| Test | Composition 27 | 53.92 | 0.50 | 10.1 | Exposure 1 | Developer 1 | Rinsing | A | A | 1.1 | 7 [symbol] |
| Example 27 | | | | | | | liquid 1 | | | | |
| Test | Composition 28 | 53.92 | 0.50 | 10.5 | Exposure 1 | Developer 1 | Rinsing | A | C | 1.1 | 7 [symbol] |
| Example 28 | | | | | | | liquid 1 | | | | |
| Test | Composition 29 | 53.92 | 0.50 | 9.9 | Exposure 1 | Developer 1 | Rinsing | A | A | 1.0 | 75 |
| Example 29 | | | | | | | liquid 1 | | | | |
| Test | Composition 30 | 53.92 | 0.50 | 10.1 | Exposure 1 | Developer 1 | Rinsing | A | A | 1.0 | 76 |
| Example 30 | | | | | | | liquid 1 | | | | |
| Test | Composition 31 | 55.00 | 0.49 | 15.6 | Exposure 1 | Developer 1 | Rinsing | A | C | 1.0 | 73 |
| Example 31 | | | | | | | liquid 1 | | | | |
| Test | Composition 32 | 53.92 | 0.50 | 14.9 | Exposure 1 | Developer 1 | Rinsing | A | A | 1.0 | 73 |
| Example 32 | | | | | | | liquid 1 | | | | |
| Test | Composition 33 | 57.03 | 0.47 | 15.6 | Exposure 1 | Developer 1 | Rinsing | A | B | 1.0 | 72 |
| Example 33 | | | | | | | liquid 1 | | | | |
| Test | Composition 34 | 53.92 | 0.50 | 22.6 | Exposure 1 | Developer 1 | Rinsing | A | B | 1.5 | 71 |
| Example 34 | | | | | | | liquid 1 | | | | |
| Test | Composition 35 | 59.62 | 0.45 | 24.6 | Exposure 1 | Developer 1 | Rinsing | A | C | 1.5 | 70 |
| Example 35 | | | | | | | liquid 1 | | | | |
| Test | Composition 36 | 60.68 | 0.44 | 3.1 | Exposure 1 | Developer 1 | Rinsing | A | A | 1.0 | 85 |
| Example 36 | | | | | | | liquid 1 | | | | |
| Test | Composition 37 | 64.43 | 0.42 | 2.5 | Exposure 1 | Developer 1 | Rinsing | B | B | 1.2 | 87 |
| Example 37 | | | | | | | liquid 1 | | | | |
| Test | Composition 38 | 68.20 | 0.40 | 3.0 | Exposure 1 | Developer 1 | Rinsing | B | B | 1.5 | 85 |
| Example 38 | | | | | | | liquid 1 | | | | |
| Test | Composition 39 | 71.47 | 0.38 | 2.9 | Exposure 1 | Developer 1 | Rinsing | C | C | 2.0 | 86 |
| Example 39 | | | | | | | liquid 1 | | | | |
| Test | Composition 40 | 53.92 | 0.50 | 10.8 | Exposure 1 | Developer 1 | Rinsing | A | A | 1.0 | 73 |
| Example 40 | | | | | | | liquid 1 | | | | |
| Test | Composition 41 | 60.61 | 0.44 | 11.1 | Exposure 1 | Developer 1 | Rinsing | B | B | 1.5 | 73 |
| Example 41 | | | | | | | liquid 1 | | | | |
| Test | Composition 42 | [symbol] 3.92 | 0.50 | 10.8 | Exposure 1 | Developer 1 | Rinsing | A | A | 1.0 | 73 |
| Example 42 | | | | | | | liquid 1 | | | | |
| Test | Composition 43 | 60.61 | 0.44 | 11.1 | Exposure 1 | Developer 1 | Rinsing | B | B | 1.5 | 73 |
| Example 43 | | | | | | | liquid 1 | | | | |
| Test | Composition R1 | 53.92 | 0.50 | 27.7 | Exposure 1 | Developer 1 | Rinsing | D | — | — | 65 |
| Example R1 | | | | | | | liquid 1 | | | | |
| Test | Composition R2 | 1.64 | 0.50 | 0. [symbol] | Exposure 1 | Developer 1 | Rinsing | D | — | — | 90 |
| Example R2 | | | | | | | liquid 1 | | | | |
| Test | Composition 1 | 53.92 | 0.50 | 10.1 | Exposure 2 | Developer 1 | Rinsing | A | A | 1.0 | 75 |
| Example 44 | | | | | | | liquid 1 | | | | |
| Test | Composition 1 | 53.92 | 0.50 | 10.1 | Exposure 1 | Developer 2 | Rinsing | A | A | 1.0 | 75 |
| Example 45 | | | | | | | liquid 1 | | | | |
| Test | Composition 1 | 53.92 | 0.50 | 10.1 | Exposure 2 | Developer 3 | Rinsing | A | A | 1.0 | 75 |
| Example 46 | | | | | | | liquid 1 | | | | |
| Test | Composition 1 | 53.92 | 0.50 | 10..1 | Exposure 2 | Developer 1 | Rinsing | A | A | 1.0 | 75 |
| Example 47 | | | | | | | liquid 2 | | | | |
| Test | Composition 1 | 53.92 | 0.50 | 10.1 | Exposure 2 | Developer 1 | Rinsing | A | A | 10 | 75 |
| Example 48 | | | | | | | liquid 3 | | | | |

[symbol]

indicates data missing or illegible when filed

As shown in the table, in Test Examples 1 to 48 in which the photocurable compositions of Compositions 1 to 43 each having an acid value of the solid content of 25 mgKOH/g or less were used and the development was performed using Developers 1 to 3 including an organic solvent, the pattern forming property and the residue were evaluated to be good.

In addition, in Test Examples R1 and R2, a pattern could not be formed, and thus, the residue and the minimum adhesive line width could not be evaluated.

In Composition 1, the same effect can be obtained even in a case where a pigment dispersion liquid prepared by replacing the C. I. Pigment Green 58 of the pigment dispersion liquid A1 with the same amount of C. I. Pigment Green 62 or C. I. pigment Green 63 was used instead of the pigment dispersion liquid A1.

In Composition 1, the same effect can be obtained even in a case where a pigment dispersion liquid prepared by replacing the C. I. Pigment Yellow 150 of the pigment dispersion liquid A1 with the same amount of C. I. Pigment Yellow 231 was used instead of the pigment dispersion liquid A1.

What is claimed is:

1. A method for producing a pattern, comprising:
a step of forming a photocurable composition layer on a support, using a photocurable composition including a color material and a resin and having an acid value of a solid content of 1 to 25 mgKOH/g;
a step of patternwise exposing the photocurable composition layer; and
a step of treating the photocurable composition layer in an unexposed area using a developer including an organic solvent, thereby performing development.

2. The method for producing a pattern according to claim 1,
wherein a solubility parameter of the organic solvent included in the developer is 18 to 24 MPa^{0.5}.

3. The method for producing a pattern according to claim 1,
wherein a CLogP value of the organic solvent included in the developer is 0 to 1.

4. The method for producing a pattern according to claim 1,
wherein the photocurable composition includes a resin having a solubility parameter such that an absolute value of a difference between the solubility parameter and a solubility parameter of the organic solvent included in the developer is 3.5 MPa^{0.5} or less.

5. The method for producing a pattern according to claim 1,
wherein the photocurable composition includes a resin having a CLogP value such that an absolute value of a difference between the CLogP value and a CLogP value of the organic solvent included in the developer is 2 or less.

6. The method for producing a pattern according to claim 1,
wherein the organic solvent included in the developer is at least one selected from a ketone-based solvent or an alcohol-based solvent.

7. The method for producing a pattern according to claim 1,
wherein the organic solvent included in the developer is at least one selected from cyclopentanone, cyclohexanone, isopropyl alcohol, or ethyl lactate.

8. The method for producing a pattern according to claim 1,
wherein the color material is a pigment.

9. The method for producing a pattern according to claim 1, further comprising a step of performing rinsing with a rinsing liquid including an organic solvent after the step of performing development.

10. The method for producing a pattern according to claim 9,
wherein a boiling point of the organic solvent included in the rinsing liquid is lower than a boiling point of the organic solvent included in the developer.

11. The method for producing a pattern according to claim 9,
wherein a solubility parameter of the organic solvent included in the rinsing liquid is 17 to 21 MPa^{0.5}.

12. The method for producing a pattern according to claim 9,
wherein a CLogP value of the organic solvent included in the rinsing liquid is 0.3 to 2.0.

13. The method for producing a pattern according to claim 9,
wherein an absolute value of a difference between a solubility parameter of the organic solvent included in the rinsing liquid and a solubility parameter of the organic solvent included in the developer is 3.5 MPa^{0.5} or less.

14. The method for producing a pattern according to claim 9,
wherein an absolute value of a difference between a CLogP value of the organic solvent included in the rinsing liquid and a CLogP value of the organic solvent included in the developer is 1.0 or less.

15. The method for producing a pattern according to claim 9,
wherein the photocurable composition includes a resin having a solubility parameter such that an absolute value of a difference between the solubility parameter and a solubility parameter of the organic solvent included in the developer is 3.5 MPa^{0.5} or less, and a solubility parameter such that an absolute value of a difference between the solubility parameter and a solubility parameter of the organic solvent included in the rinsing liquid is 5.5 MPa^{0.5} or less.

16. The method for producing a pattern according to claim 9,
wherein the photocurable composition includes a resin having a CLogP value such that an absolute value of a difference between the CLogP value and a CLogP value of the organic solvent included in the developer is 2 or less, and a CLogP value such that an absolute value of a difference between the CLogP value and a CLogP value of the organic solvent included in the rinsing liquid is 0.5 to 3.

17. A method for manufacturing an optical filter, comprising the method for producing a pattern according to claim 1.

18. A method for manufacturing a solid-state imaging element, comprising the method for producing a pattern according to claim 1.

19. A method for manufacturing an image display device, comprising the method for producing a pattern according to claim 1.

20. A photocurable composition used in the method for producing a pattern according to claim 1, comprising:
a color material; and
a resin,
wherein an acid value of a solid content is 1 to 25 mgKOH/g.

21. A photocurable composition comprising:
a color material; and
a resin, and
wherein an acid value of a solid content is 1 to 25 mgKOH/g, and
the photocurable composition satisfies Condition 1;
Condition 1: in a case where the photocurable composition is applied onto a glass substrate and heated at 100° C. for 2 minutes to form a film, a contact angle of a film surface with respect to pure water after a lapse of 3,000 ms from dropping of 8 μL of the pure water onto the film is 70° to 120°.

22. A film comprising:
a color material; and
a resin, and
wherein an acid value of a solid content is 1 to 25 mgKOH/g, and
a contact angle of a film surface with respect to pure water after a lapse of 3,000 ms from dropping of 8 μL of the pure water onto the film is 70° to 120°.
